(19) United States
(12) Patent Application Publication
(10) Pub. No.: US 2026/0313843 A1
(43) Pub. Date: Oct. 8, 2026

(54) ELECTRONIC DEVICE INCLUDING VAPOR CHAMBER

(71) Applicant: SAMSUNG ELECTRONICS CO., LTD., Suwon-si (KR)

(72) Inventors: Changi PARK, Suwon-si (KR); Gyudae JANG, Suwon-si (KR); Jooyeol RYU, Suwon-si (KR); Hyunmuk KIM, Suwon-si (KR); Minho KIM, Suwon-si (KR); Namwoo KIM, Suwon-si (KR); Jeongho KANG, Suwon-si (KR)

(73) Assignee: SAMSUNG ELECTRONICS CO., LTD., Suwon-si (KR)

(21) Appl. No.: 19/444,970

(22) Filed: Jan. 9, 2026

Related U.S. Application Data
(63) Continuation of application No. PCT/KR2025/023062, filed on Dec. 29, 2025.

(30) Foreign Application Priority Data
Apr. 2, 2025 (KR) 10-2025-0042666
Apr. 17, 2025 (KR) 10-2025-0050529

(51) Int. Cl. H05K 7/20; H05K 5/02

(52) U.S. Cl. CPC H05K 7/20336; H05K 5/02; H05K 7/20309; H05K 7/20318

(57) ABSTRACT

An electronic device includes: a housing; a first heat source and a second heat source in the housing; a vapor chamber between the first heat source and the second heat source. The vapor chamber includes: a first plate to be closer to the first heat source than the second heat source, a second plate to be closer to the second heat source than the first heat source, a first wick in the internal space and in contact with at least a part of an inner side of the first plate. The first wick includes a plurality of first holes. A second wick is disposed in the internal space and in contact with at least a part of an inner side of the second plate. The second wick includes a plurality of second holes.

### CROSS-REFERENCE TO RELATED APPLICATIONS

This application is a by-pass continuation application of International Application No. PCT/KR 2025/023062, filed on Dec. 29, 2025, which is based on and claims priority to Korean Patent Application No. 10-2025-0042666, filed on Apr. 2, 2025, and Korean patent application number 10-2025-0050529, filed on Apr. 17, 2025, in the Korean Intellectual Property Office, the disclosures of which are incorporated by reference herein their entireties.

### BACKGROUND

### 1. Field

The disclosure relates to an electronic device including a vapor chamber.

### 2. Description of Related Art

An electronic device may include various electronic components. Electronic components in the electronic device may generate heat. For example, heat generated by an electronic component may degrade a performance of the electronic component and other electronic components. In order to dissipate the heat generated by the electronic component, the electronic device may include a vapor chamber.

The above-described information may be provided as related art for the purpose of helping understanding of the present disclosure. No argument or decision is made as to whether any of the above description may be applied as prior art related to the present disclosure.

### SUMMARY

According to an aspect of the disclosure, an electronic device includes: a housing; a display panel defining at least a part of a front side of the housing; a display driver integrated circuit (DDI) connected to the display panel and closer to a top side of the housing than a bottom side of the housing; a processor in the housing and including processing circuitry; and a vapor chamber between the DDI and the processor, wherein the vapor chamber includes: a first heat conductivity member configured to dissipate heat generated by the DDI, the first heat conductivity member including a first plate and a first wick in contact with the first plate, and a second heat conductivity member configured to dissipate heat generated by the processor, the second heat conductivity member including a second plate and a second wick in contact with the second plate, wherein the first wick and the second wick are in an internal space between the first plate and the second plate, wherein the first wick includes a first evaporation portion overlapping at least a part of the DDI and receiving the heat generated by the DDI, a first condensation portion spaced apart from the DDI and receiving the heat from the DDI, and a first path portion connecting the first evaporation portion to the first condensation portion, wherein the second wick includes a second evaporation portion overlapping at least a part of the processor and receiving the heat generated by the processor, a second condensation portion spaced apart from the processor, and a second path portion connecting the second evaporation portion to the second condensation portion, and wherein the first path portion of the first wick and the second path portion of the second wick do not overlap each other.

According to an aspect of the disclosure, an electronic device includes: a housing; a first heat source in the housing; a second heat source in the housing; a vapor chamber between the first heat source and the second heat source, wherein the vapor chamber includes: a first plate that is closer to the first heat source than the second heat source, a second plate that is closer to the second heat source than the first heat source, the second plate being coupled to the first plate to define an internal space between the first plate and the second plate, a first wick in the internal space and in contact with at least a part of an inner side of the first plate, the first wick including a plurality of first holes, and a second wick in the internal space and in contact with at least a part of an inner side of the second plate, the second wick including a plurality of second holes, wherein the first plate includes a first support area in a first inner direction of the vapor chamber and including a first set of protruding portions penetrating the plurality of first holes in the first wick, and a first heat source area on which the first set of the protruding portions are not disposed, and directly contacting the first heat source or indirectly contacting the first heat source through at least one component, and wherein the second plate includes a second support area in a second inner direction of the vapor chamber and including a second set of protruding portions penetrating the plurality of second holes in the second wick, and a second heat source area on which the second set of the protruding portions are not disposed, and directly contacting the second heat source or indirectly contacting the second heat source through at least one component.

In embodiments of the present disclosure, an electronic device is provided. The electronic device may comprise a housing, a display panel defining at least a part of a front side of the housing, a display driver integrated circuit (DDI) connected to the display panel and disposed to be closer to a top side of the housing than a bottom side of the housing, a processor comprising processing circuitry and disposed in the housing, and a vapor chamber disposed between the DDI and the processor. The vapor chamber may include a first heat conductivity member disposed to dissipate heat generated by the DDI and including a first plate and a first wick in contact with the first plate, and a second heat conductivity member disposed to dissipate heat generated by the processor and including a second plate and a second wick in contact with the second plate. The first wick may be disposed in an internal space disposed between the first plate and the second plate. The first wick may include a first evaporation portion overlapping at least a part of the DDI and receiving heat generated by the DDI, a first condensation portion spaced apart from the DDI and receiving heat from the DDI, and a first path portion connecting the first evaporation portion to the first condensation portion. The second wick may be disposed in the internal space. The second wick may include a second evaporation portion overlapping at least a part of the processor and receiving heat generated by the processor, a second condensation portion spaced apart from the processor, and a second path portion connecting the second evaporation portion to the second condensation portion. The first path portion of the first wick and the second path portion of the second wick may not overlap each other.

In embodiments of the present disclosure, an electronic device is provided. The electronic device may comprise a housing, a display panel defining at least a part of a front side of the housing, a display driver circuit (DDI) connected to the display panel disposed to be closer to a top side of the housing than a bottom side of the housing, a processor comprising processing circuitry and disposed in the housing, and a vapor chamber disposed between the DDI and the processor. The vapor chamber may include a first heat conductivity member disposed to dissipate heat generated by the DDI and including a first plate and a first wick in contact with the first plate, and a second heat conductivity member disposed to dissipate heat generated by the processor and including a second plate and a second wick in contact with the second plate. Each of the first wick and second wick may be disposed in an internal space disposed between the first plate and the second plate. The first plate may have a first set of protruding portions disposed on an inner side of the first plate. The second plate may have a second set of protruding portions disposed on an inner side of the second plate. The first wick may comprise holes for protruding portions included in the first set of the protruding portions. The second wick may comprise holes for protruding portions included in the second set of the protruding portions.

In embodiments of the present disclosure, an electronic device is provided. The electronic device may comprise a housing, a first heat source and a second heat source disposed in the housing, and a vapor chamber disposed between the first heat source and the second heat source. The vapor chamber may include a first plate disposed to be closer to the first heat source than the second heat source, a second plate disposed to be closer to the second heat source than the first heat source, the second plate coupled to the first plate to define an internal space between the first plate and the second plate, a first wick disposed in the internal space and in contact with at least a part of an inner side of the first plate, the first wick including a plurality of holes, and a second wick disposed in the internal space and in contact with at least a part of an inner side of the second plate, the second wick including a plurality of holes. The first plate may include a first support area formed in an inner direction of the vapor chamber and having a first set of protruding portions penetrating a plurality of holes included in the first wick, and a first heat source area on which the first set of the protruding portions are not disposed, directly contacting the first heat source or indirectly contacting the first heat source through at least one component. The second plate may include a second support area formed in an inner direction of the vapor chamber and having a second set of protruding portions penetrating a plurality of holes included in the second wick, and a second heat source area on which the second set of the protruding portions are not disposed, directly contacting the second heat source or indirectly contacting the second heat source through at least one component.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a block diagram of an electronic device in a network environment;

FIG. 2 is a perspective view of an electronic device including a vapor chamber;

FIG. 3A is a diagram for describing a principle of a vapor chamber;

FIG. 3B indicates examples of components of a vapor chamber and electronic components;

FIGS. 4A, 4B, and 4C indicate examples of components of a vapor chamber;

FIG. 5 indicates an example of a disposition of a display driver circuit, at least one processor, and a vapor chamber;

FIG. 6 indicates an example of a vapor chamber including a first wick and a second wick;

FIGS. 7A and 7B indicate examples of a vapor chamber of plates having protruding portions;

FIG. 8 indicates an example of an overlapping structure of a first wick and a second wick;

FIGS. 9A, 9B, and 9C indicate examples of a shape of the second wick for at least one processor;

FIGS. 10A, 10B, and 10C indicate examples of components of a vapor chamber;

FIGS. 11A, 11B, and 11C indicate examples of an overlapping structure of the first wick and the second wick;

FIG. 12 indicates an example of a disposition of a display driver circuit for heat dissipation;

FIG. 13 indicates an example of a disposition of at least one processor for heat dissipation;

FIG. 14 indicates an example of a vapor chamber using an etching method;

FIG. 15 indicates an example of a vapor chamber of a curved shape;

FIG. 16 indicates an example of a vapor chamber having a single welding side;

FIGS. 17A, 17B, 17C, 17D, and 17E indicate examples of a vapor chamber having a curved welding side;

FIGS. 18A, 18B, 18C, and 19 indicate examples of a disposition of a display driver circuit and a camera at a top side of an electronic device;

FIG. 20 indicates an example of a battery in an electronic device including a slope-shape back cover; and

FIGS. 21A, 21B, and 21C indicate examples of components forming a back volume space for a speaker.

### DETAILED DESCRIPTION

Terms used in the present disclosure are used only to describe a specific embodiment, and may not be intended to limit a range of another embodiment. A singular expression may include a plural expression unless the context clearly means otherwise. Terms used herein, including a technical or a scientific term, may have the same meaning as those generally understood by a person with ordinary skill in the art described in the present disclosure. Among the terms used in the present disclosure, terms defined in a general dictionary may be interpreted as identical or similar meaning to the contextual meaning of the relevant technology and are not interpreted as ideal or excessively formal meaning unless explicitly defined in the present disclosure. In some cases, even terms defined in the present disclosure may not be interpreted to exclude embodiments of the present disclosure.

In various embodiments of the present disclosure described below, a hardware approach will be described as an example. However, since the various embodiments of the present disclosure include technology that uses both hardware and software, the various embodiments of the present disclosure do not exclude a software-based approach.

A term (e.g., a substrate, a printed circuit board (PCB), a flexible PCB (FPCB), a module, an element, circuitry, integrated circuit (IC), a processor, a chip, a component, a device) referring to a component of an electronic device, a term (e.g., a structure, a construction, a support, a contact, a protrusion) referring to a shape of a component, a term (e.g., a connection, a contact, a support, a contact structure, a conductive member, an assembly) referring to a connection between structures, and the like, used in the following description are exemplified for convenience of description. Therefore, the present disclosure is not limited to terms to be described below, and another term having an equivalent technical meaning may be used. In addition, a term such as ‘. . . unit’, ‘. . . device’, ‘. . . object’, and ‘. . . structure’, and the like used below may mean at least one shape structure or may mean a unit processing a function.

In addition, in the present disclosure, the term ‘greater than’ or ‘less than’ may be used to determine whether a particular condition is satisfied or fulfilled, but this is only a description to express an example and does not exclude description of ‘greater than or equal to’ or ‘less than or equal to’. A condition described as ‘greater than or equal to’ may be replaced with ‘greater than’, a condition described as ‘less than or equal to’ may be replaced with ‘less than’, and a condition described as ‘greater than or equal to and less than’ may be replaced with ‘greater than and less than or equal to’. In addition, hereinafter, ‘A’ to ‘B’ refers to at least one of elements from A (including A) to B (including B). Hereinafter, ‘C’ and/or ‘D’ means including at least one of ‘C’ or ‘D’, that is, {‘C’, ‘D’, and ‘C’ and ‘D’}.

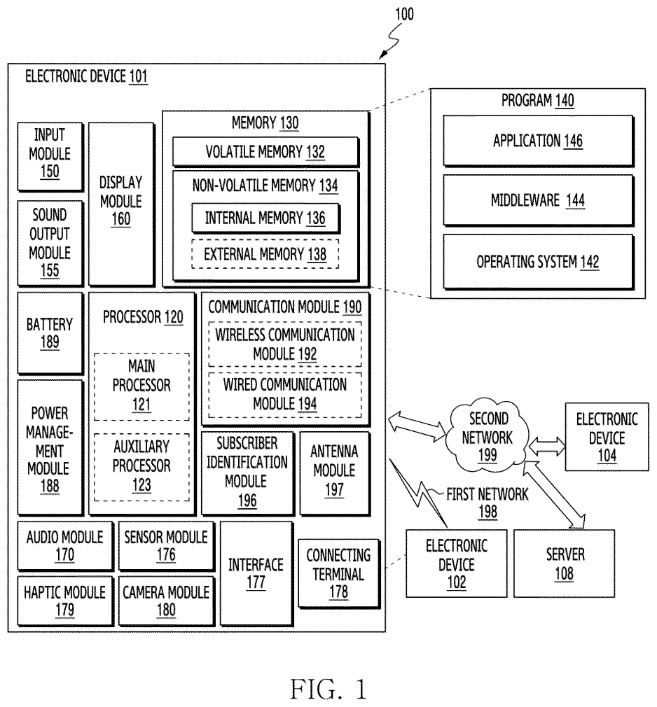

FIG. 1 is a block diagram illustrating an electronic device 101 in a network environment 100 according to various embodiments.

Referring to FIG. 1, the electronic device 101 in the network environment 100 may communicate with an electronic device 102 via a first network 198 (e.g., a short-range wireless communication network), or at least one of an electronic device 104 or a server 108 via a second network 199 (e.g., a long-range wireless communication network). According to an embodiment, the electronic device 101 may communicate with the electronic device 104 via the server 108. According to an embodiment, the electronic device 101 may include at least one processor 120, memory 130, an input module 150, a sound output module 155, a display module 160, an audio module 170, a sensor module 176, an interface 177, a connecting terminal 178, a haptic module 179, a camera module 180, a power management module 188, a battery 189, a communication module 190, a subscriber identification module (SIM) 196, or an antenna module 197. In some embodiments, at least one of the components (e.g., the connecting terminal 178) may be omitted from the electronic device 101, or one or more other components may be added in the electronic device 101. In some embodiments, some of the components (e.g., the sensor module 176, the camera module 180, or the antenna module 197) may be implemented as a single component (e.g., the display module 160).

The processor 120 may execute, for example, software (e.g., a program 140) to control at least one other component (e.g., a hardware or software component) of the electronic device 101 coupled with the processor 120, and may perform various data processing or computation. According to an embodiment, as at least part of the data processing or computation, the processor 120 may store a command or data received from another component (e.g., the sensor module 176 or the communication module 190) in volatile memory 132, process the command or the data stored in the volatile memory 132, and store resulting data in non-volatile memory 134. According to an embodiment, the processor 120 may include a main processor 121 (e.g., a central processing unit (CPU) or an application processor (AP)), or an auxiliary processor 123 (e.g., a graphics processing unit (GPU), a neural processing unit (NPU), an image signal processor (ISP), a sensor hub processor, or a communication processor (CP)) that is operable independently from, or in conjunction with, the main processor 121. For example, when the electronic device 101 includes the main processor 121 and the auxiliary processor 123, the auxiliary processor 123 may be adapted to consume less power than the main processor 121, or to be specific to a specified function. The auxiliary processor 123 may be implemented as separate from, or as part of the main processor 121.

The auxiliary processor 123 may control at least some of functions or states related to at least one component (e.g., the display module 160, the sensor module 176, or the communication module 190) among the components of the electronic device 101, instead of the main processor 121 while the main processor 121 is in an inactive (e.g., sleep) state, or together with the main processor 121 while the main processor 121 is in an active state (e.g., executing an application). According to an embodiment, the auxiliary processor 123 (e.g., an image signal processor or a communication processor) may be implemented as part of another component (e.g., the camera module 180 or the communication module 190) functionally related to the auxiliary processor 123. According to an embodiment, the auxiliary processor 123 (e.g., the neural processing unit) may include a hardware structure specified for artificial intelligence model processing. An artificial intelligence model may be generated by machine learning. Such learning may be performed, e.g., by the electronic device 101 where the artificial intelligence is performed or via a separate server (e.g., the server 108). Learning algorithms may include, but are not limited to, e.g., supervised learning, unsupervised learning, semi-supervised learning, or reinforcement learning. The artificial intelligence model may include a plurality of artificial neural network layers. The artificial neural network may be a deep neural network (DNN), a convolutional neural network (CNN), a recurrent neural network (RNN), a restricted Boltzmann machine (RBM), a deep belief network (DBN), a bidirectional recurrent deep neural network (BRDNN), deep Q-network or a combination of two or more thereof but is not limited to the above examples. The artificial intelligence model may, additionally or alternatively, include a software structure other than the hardware structure.

The memory 130 may store various data used by at least one component (e.g., the processor 120 or the sensor module 176) of the electronic device 101. The various data may include, for example, software (e.g., the program 140) and input data or output data for a command related to the software. The memory 130 may include the volatile memory 132 or the non-volatile memory 134.

The program 140 may be stored in the memory 130 as software, and may include, for example, an operating system (OS) 142, middleware 144, or an application 146.

The input module 150 may receive a command or data to be used by another component (e.g., the processor 120) of the electronic device 101, from the outside (e.g., a user) of the electronic device 101. The input module 150 may include, for example, a microphone, a mouse, a keyboard, a key (e.g., a button), or a digital pen (e.g., a stylus pen).

The sound output module 155 may output sound signals to the outside of the electronic device 101. The sound output module 155 may include, for example, a speaker or a receiver. The speaker may be used for general purposes, such as playing multimedia or playing record. The receiver may be used for receiving incoming calls. According to an embodiment, the receiver may be implemented as separate from, or as part of the speaker.

The display module 160 may visually provide information to the outside (e.g., a user) of the electronic device 101. The display module 160 may include, for example, a display, a hologram device, or a projector and control circuitry to control a corresponding one of the display, hologram device, and projector. According to an embodiment, the display module 160 may include a touch sensor adapted to detect a touch, or a pressure sensor adapted to measure the intensity of force incurred by the touch.

The audio module 170 may convert a sound into an electrical signal and vice versa. According to an embodiment, the audio module 170 may obtain the sound via the input module 150, or output the sound via the sound output module 155 or a headphone of an external electronic device (e.g., an electronic device 102) directly (e.g., through a wire or wires) or wirelessly coupled with the electronic device 101.

The sensor module 176 may detect an operational state (e.g., power or temperature) of the electronic device 101 or an environmental state (e.g., a state of a user) external to the electronic device 101, and then generate an electrical signal or data value corresponding to the detected state. According to an embodiment, the sensor module 176 may include, for example, a gesture sensor, a gyro sensor, an atmospheric pressure sensor, a magnetic sensor, an acceleration sensor, a grip sensor, a proximity sensor, a color sensor, an infrared (IR) sensor, a biometric sensor, a temperature sensor, a humidity sensor, or an illuminance sensor.

The interface 177 may support one or more specified protocols to be used for the electronic device 101 to be coupled with the external electronic device (e.g., the electronic device 102) directly (e.g., through a wire or wires) or wirelessly. According to an embodiment, the interface 177 may include, for example, a high definition multimedia interface (HDMI), a universal serial bus (USB) interface, a secure digital (SD) card interface, or an audio interface.

A connecting terminal 178 may include a connector via which the electronic device 101 may be physically connected with the external electronic device (e.g., the electronic device 102). According to an embodiment, the connecting terminal 178 may include, for example, an HDMI connector, a USB connector, an SD card connector, or an audio connector (e.g., a headphone connector).

The haptic module 179 may convert an electrical signal into a mechanical stimulus (e.g., a vibration or a movement) or electrical stimulus which may be recognized by a user via his tactile sensation or kinesthetic sensation. According to an embodiment, the haptic module 179 may include, for example, a motor, a piezoelectric element, or an electric stimulator.

The camera module 180 may capture a still image or moving images. According to an embodiment, the camera module 180 may include one or more lenses, image sensors, image signal processors, or flashes.

The power management module 188 may manage power supplied to the electronic device 101. According to an embodiment, the power management module 188 may be implemented as at least part of, for example, a power management integrated circuit (PMIC).

The battery 189 may supply power to at least one component of the electronic device 101. According to an embodiment, the battery 189 may include, for example, a primary cell which is not rechargeable, a secondary cell which is rechargeable, or a fuel cell.

The communication module 190 may support establishing a direct (e.g., wired) communication channel or a wireless communication channel between the electronic device 101 and the external electronic device (e.g., the electronic device 102, the electronic device 104, or the server 108) and performing communication via the established communication channel. The communication module 190 may include one or more communication processors that are operable independently from the processor 120 (e.g., the application processor (AP)) and supports a direct (e.g., wired) communication or a wireless communication. According to an embodiment, the communication module 190 may include a wireless communication module 192 (e.g., a cellular communication module, a short-range wireless communication module, or a global navigation satellite system (GNSS) communication module) or a wired communication module 194 (e.g., a local area network (LAN) communication module or a power line communication (PLC) module). A corresponding one of these communication modules may communicate with the external electronic device via the first network 198 (e.g., a short-range communication network, such as Bluetooth™, wireless-fidelity (Wi-Fi) direct, or infrared data association (IrDA)) or the second network 199 (e.g., a long-range communication network, such as a legacy cellular network, a 5G network, a next-generation communication network, the Internet, or a computer network (e.g., LAN or wide area network (WAN)). These various types of communication modules may be implemented as a single component (e.g., a single chip), or may be implemented as multi components (e.g., multi chips) separate from each other. The wireless communication module 192 may identify and authenticate the electronic device 101 in a communication network, such as the first network 198 or the second network 199, using subscriber information (e.g., international mobile subscriber identity (IMSI)) stored in the subscriber identification module 196.

The wireless communication module 192 may support a 5G network, after a 4G network, and next-generation communication technology, e.g., new radio (NR) access technology. The NR access technology may support enhanced mobile broadband (eMBB), massive machine type communications (mMTC), or ultra-reliable and low-latency communications (URLLC). The wireless communication module 192 may support a high-frequency band (e.g., the mmWave band) to achieve, e.g., a high data transmission rate. The wireless communication module 192 may support various technologies for securing performance on a high-frequency band, such as, e.g., beamforming, massive multiple-input and multiple-output (massive MIMO), full dimensional MIMO (FD-MIMO), array antenna, analog beam-forming, or large scale antenna. The wireless communication module 192 may support various requirements specified in the electronic device 101, an external electronic device (e.g., the electronic device 104), or a network system (e.g., the second network 199). According to an embodiment, the wireless communication module 192 may support a peak data rate (e.g., 20 Gbps or more) for implementing eMBB, loss coverage (e.g., 164 dB or less) for implementing mMTC, or U-plane latency (e.g., 0.5 ms or less for each of downlink (DL) and uplink (UL), or a round trip of 1 ms or less) for implementing URLLC.

The antenna module 197 may transmit or receive a signal or power to or from the outside (e.g., the external electronic device) of the electronic device 101. According to an embodiment, the antenna module 197 may include an antenna including a radiating element composed of a conductive material or a conductive pattern formed in or on a substrate (e.g., a printed circuit board (PCB)). According to an embodiment, the antenna module 197 may include a plurality of antennas (e.g., array antennas). In such a case, at least one antenna appropriate for a communication scheme used in the communication network, such as the first network 198 or the second network 199, may be selected, for example, by the communication module 190 (e.g., the wireless communication module 192) from the plurality of antennas. The signal or the power may then be transmitted or received between the communication module 190 and the external electronic device via the selected at least one antenna. According to an embodiment, another component (e.g., a radio frequency integrated circuit (RFIC)) other than the radiating element may be additionally formed as part of the antenna module 197.

According to various embodiments, the antenna module 197 may form a mmWave antenna module. According to an embodiment, the mmWave antenna module may include a printed circuit board, an RFIC disposed on a first surface (e.g., the bottom surface) of the printed circuit board, or adjacent to the first surface and capable of supporting a designated high-frequency band (e.g., the mmWave band), and a plurality of antennas (e.g., array antennas) disposed on a second surface (e.g., the top or a side surface) of the printed circuit board, or adjacent to the second surface and capable of transmitting or receiving signals of the designated high-frequency band.

At least some of the above-described components may be coupled mutually and communicate signals (e.g., commands or data) therebetween via an inter-peripheral communication scheme (e.g., a bus, general purpose input and output (GPIO), serial peripheral interface (SPI), or mobile industry processor interface (MIPI)).

According to an embodiment, commands or data may be transmitted or received between the electronic device 101 and the external electronic device 104 via the server 108 coupled with the second network 199. Each of the electronic devices 102 or 104 may be a device of a same type as, or a different type, from the electronic device 101. According to an embodiment, all or some of operations to be executed at the electronic device 101 may be executed at one or more of the external electronic devices 102, 104, or 108. For example, if the electronic device 101 should perform a function or a service automatically, or in response to a request from a user or another device, the electronic device 101, instead of, or in addition to, executing the function or the service, may request the one or more external electronic devices to perform at least part of the function or the service. The one or more external electronic devices receiving the request may perform the at least part of the function or the service requested, or an additional function or an additional service related to the request, and transfer an outcome of the performing to the electronic device 101. The electronic device 101 may provide the outcome, with or without further processing of the outcome, as at least part of a reply to the request. To that end, a cloud computing, distributed computing, mobile edge computing (MEC), or client-server computing technology may be used, for example. The electronic device 101 may provide ultra-low-latency services using, e.g., distributed computing or mobile edge computing. In another embodiment, the external electronic device 104 may include an internet-of-things (IoT) device. The server 108 may be an intelligent server using machine learning and/or a neural network. According to an embodiment, the external electronic device 104 or the server 108 may be included in the second network 199. The electronic device 101 may be applied to intelligent services (e.g., smart home, smart city, smart car, or healthcare) based on 5G communication technology or IoT-related technology.

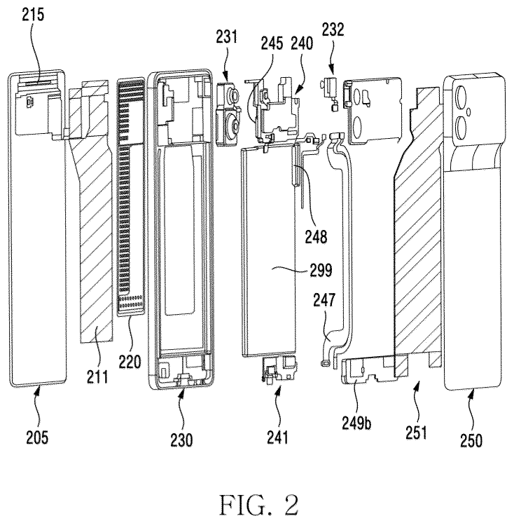

FIG. 2 is a perspective view of an electronic device (e.g., an electronic device 101) including a vapor chamber.

Referring to FIG. 2, the electronic device 101 may include a housing that is an exterior of the electronic device 101. For example, the electronic device 101 may include a metal frame 230 that correspond to lateral sides of the electronic device 101. For example, the electronic device 101 may include a rear cover 250. The electronic device 101 may include a display panel 205 (e.g., the display module 160). The display panel 205 may define a front side of the housing.

The electronic device 101 may include components for functions of the electronic device 101. For example, the electronic device 101 may include a display driver circuit 215 (e.g., a display driver integrated circuit (DDI)), a rear camera 231 (e.g., the camera module 180), a front camera 232 (e.g., the camera module 180), a printed board assembly (PBA) 240, a sub-PCB 241, a power FPCB 247, side key circuitry 248, a bottom side speaker 249b, and/or a battery 299 (e.g., a battery 189). The PBA 240 may include at least one processor. For example, the PBA 240 may include at least one processor 245 (e.g., the processor 120). The electronic device 101 may include components for dissipate heat of components in the electronic device 101 and emitting the heat to an outside. For example, the electronic device 101 may include a first graphite 211, a second graphite 251, and/or a vapor chamber 220.

The display driver circuit 215 may be used to control a color (e.g., red green blue (RGB)) of sub-pixels of an image displayed through the display panel 205. The display driver circuit 215 may be connected to the display panel 205. For example, the display driver circuit 215 may be disposed on a substrate (e.g., a polyimide (PI) substrate, a glass substrate, or a film substrate). According to an embodiment, the display driver circuit 215 may be disposed closer to a top side of the electronic device 101 than a bottom side of the electronic device 101. To increase a capacity of the battery 299, it may be required to sufficiently secure a width of the battery 299. For example, as at least a part of the battery 299 is positioned at the bottom side of the electronic device 101, the display driver circuit 215 may be disposed in an area corresponding to the top side of the electronic device 101. As the display driver circuit 215 is disposed in the area corresponding to the top side of the electronic device 101, a substrate on which the display driver circuit 215 is disposed and a flexible printed circuit board (FPCB) connected to the substrate may be disposed closer to the top side of the electronic device 101 than the bottom side of the electronic device 101 as it is disposed closer to the top side of the electronic device 101. For this reason, a mounting space in the housing of the electronic device 101 may be efficiently used as a display connector is connectable to the substrate (e.g., PCB) of the PBA 240. However, as a distance between the at least one processor (e.g., the processor 245) and the display driver circuit 215 approaches, a heat dissipation structure may be required to reduce heat generation.

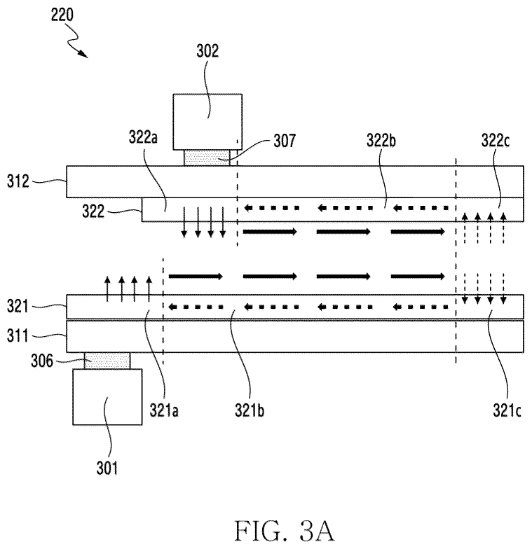

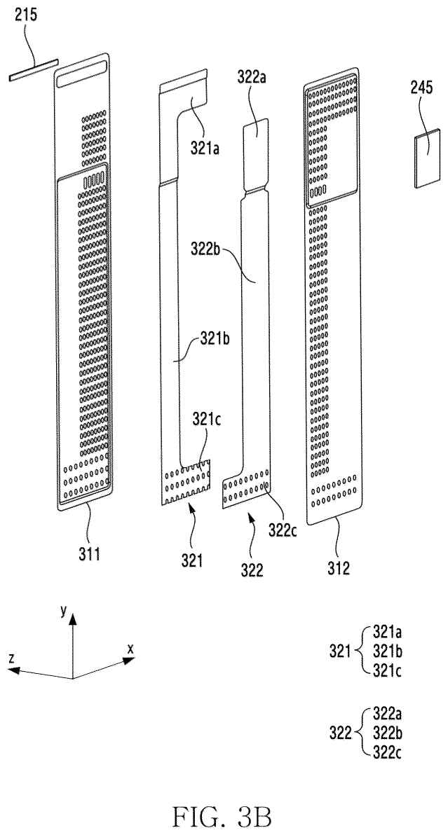

FIG. 3A is a diagram for describing a principle of a vapor chamber (e.g., a vapor chamber 220). For the same descriptions, the same reference number may be used.

Referring to FIG. 3A, the vapor chamber 220 may include a first plate 311, a second plate 312, a first wick 321, and a second wick 322. In the present disclosure, the ‘wick’ is a part or a piece of heat dissipating materials such as a metal. For example, FIGS. 3A and 3B shows non-limiting examples of the ‘wick’ such as the first wick 321, and the second wick 322. The vapor chamber 220 may be used for two heat sources (e.g., a first heat source 301 and a second heat source 302). For example, the first heat source 301 may include or correspond to a display driver circuit 215 (e.g., a first processor). The second heat source 302 may include or correspond to a processor 245 (e.g., a second processor). Heat from each heat source may be transmitted to the vapor chamber 220 through one or more components (e.g., a thermal interface material (TIM), and a shielding sheet). For example, heat from the first heat source 301 may be transmitted to the vapor chamber 220 through a TIM 306. As an example, the first plate 311 may be in contact with the TIM 306. For example, heat from the second heat source 302 may be transmitted to the vapor chamber 220 through a TIM 307. As an example, the second plate 312 may be in contact with the TIM 307.

The vapor chamber 220 may include a heat dissipation structure for two heat sources (e.g., the first heat source 301 and the second heat source 302). The vapor chamber 220 may include the first plate 311 and the first wick 321 for the first heat source 301, and the second plate 312 and the second wick 322 for the second heat source 302. The first plate 311 may be used to transmit heat from the first heat source 301. The first heat source 301 may be disposed closer to the first plate 311 than the second plate 312. The second plate 312 may be used to transmit heat from the second heat source 302. The second heat source 302 may be disposed closer to the second plate 312 than the first plate 311. The first plate 311 and the second plate 312 may be coupled to form an internal space between the vapor chambers 220. For example, the first plate 311 and the second plate 312 may form a volume through welding. The first wick 321 may be in contact with the first plate 311 on the internal space. The second wick 322 may be in contact with the second plate 312 on the internal space. As a non-limiting example, the internal space may be in a low pressure state close to a vacuum.

Heat may be dissipated through movement of steam on the internal space between the first plate 311 and the second plate 312 and a capillary phenomenon at each wick (e.g., the first wick 321, or the second wick 322). For example, according to heat transmitted through the first plate 311, a refrigerant in an area (hereinafter, an evaporation portion) adjacent to the first heat source 301 may be vaporized. Steam formed through vaporization may move through the internal space. Thereafter, steam in an area (hereinafter, a condensation portion) far from a heat source may be liquefied. A liquefied material may move to the evaporation portion through a capillary phenomenon of the first wick 321. Heat may be dissipated through this circulation. For example, according to heat transmitted through the second plate 312, a refrigerant in an area (hereinafter, an evaporation portion) adjacent to the second heat source 302 may be vaporized. Steam formed through vaporization may move through the internal space. Thereafter, steam in an area (hereinafter, a condensation portion) far from a heat source may be liquefied. A liquefied material may move to the evaporation portion through a capillary phenomenon of the second wick 322. Heat may be dissipated through this circulation.

FIG. 3B indicates examples of components of a vapor chamber (e.g., the vapor chamber 220) and electronic components. In FIG. 3B, similar to FIG. 3A, a structure of the vapor chamber 220 for heat dissipation of the display driver circuit (e.g., the display driver circuit 215) and at least one processor (e.g., the processor 245) is described. For the same descriptions, the same reference number may be used.

Referring to FIG. 3B, the vapor chamber 220 may be disposed between the display driver circuit 215 and the processor 245. The vapor chamber 220 may include the first plate 311, the second plate 312, the first wick 321, and the second wick 322. The first plate 311 may include a first side (e.g., a side facing a (+)z-axis) and a second side (e.g., a side facing a (−)z-axis) opposite to the first side. The second plate 312 may include a first side (e.g., a side facing the (-)z-axis) and a second side (e.g., a side facing the (+)z-axis) opposite to the first side.

The display driver circuit 215 may be disposed close to the first side of the first side and the second side of the first plate 311. For example, the display driver circuit 215 may be disposed over the first side of the first plate 311. The display driver circuit 215 may be disposed to transmit heat generated by the display driver circuit 215 to the first plate 311 of the vapor chamber 220 through one or more components. For example, the display driver circuit 215 may be physically connected to the first plate 311 through the TIM and/or the shielding sheet. The processor 245 may be disposed close to the first side of the first side and the second side of the second plate 312. For example, the processor 245 may be disposed over the first side of the second plate 312. The processor 245 may be disposed to transmit heat generated by the display driver circuit 215 to the second plate 312 of the vapor chamber 220 through one or more components. For example, the processor 245 may be physically connected to the second plate 312 through a tape, the TIM, a metal structure, and/or the heat dissipation sheet. The second side of the first plate 311 and the second side of the second plate 312 may be disposed to face each other. An internal space may be formed through coupling of the first plate 311 and the second plate 312. The second side of the first plate 311 may be in contact with the first wick 321 in the internal space. The second side of the second plate 312 may be in contact with the second wick 322 in the internal space.

The vapor chamber 220 may have a structure for heat dissipation. In order to dissipate heat, phase conversion (e.g., liquefaction or vaporization) and a capillary phenomenon of the refrigerant may be used. According to an embodiment, the first wick 321 may include a first evaporation portion 321a, a first path portion 321b, and a first condensation portion 321c. The first path portion 321b may be disposed between the first evaporation portion 321a and the first condensation portion 321c. The first evaporation portion 321a may overlap the display driver circuit 215. For example, when viewed in a direction (e.g., the (+)z-axis direction), the first evaporation portion 321a may overlap the display driver circuit 215. The first condensation portion 321c may not overlap the display driver circuit 215. For example, when viewed in the direction (e.g., the (+)z-axis direction), the first condensation portion 321c may not overlap the display driver circuit 215. Vaporization may be performed in the first evaporation portion 321a through heat of the display driver circuit 215. Liquefaction for steam may be performed in the first condensation portion 321c. Refrigerant obtained through the liquefaction may be transmitted back to the first evaporation portion 321a through the first path portion 321b. Heat may be dissipated through this circulation.

According to an embodiment, the second wick 322 may include a second evaporation portion 322a, a second path portion 322b, and a second condensation portion 322c. The second path portion 322b may be disposed between the second evaporation portion 322a and the second condensation portion 322c. The second evaporation portion 322a may overlap the processor 245. For example, when viewed in a direction (e.g., the (-z)-axis direction), the second evaporation portion 322a may overlap the processor 245. The second condensation portion 322c may not overlap the processor 245. For example, when viewed in a direction (e.g., the (-)z-axis direction), the second condensation portion 322c may not overlap the processor 245. Vaporization may be performed in the second evaporation portion 322a through heat of the processor 245. Liquefaction for steam may be performed in the second condensation portion 322c. The refrigerant obtained through the liquefaction may be transmitted back to the second evaporation portion 322a through the second path portion 322b. Heat may be dissipated through such circulation.

According to embodiments of the present disclosure, when viewed in the direction (e.g., the (+)z-axis direction), at least a part of the first wick 321 may not overlap at least a part of the second wick 322. In a case that a wick is entirely disposed on each of the second side of the first plate 311 and the second side of the second plate 312 at a limited thickness, a moving path of the steam may be narrowed due to a thickness of the wick. Because the moving path of steam may be narrowed, thermal resistance may increase. In order to secure the sufficient moving path of the steam in a limited thickness, the at least a part of the first wick 321 and the at least a part of the second wick 322 may be disposed in order not to overlap each other when viewed in a direction (e.g., the z-axis direction). For example, the at least a part of the first wick 321 and the at least a part of the second wick 322 may be disposed in different areas based on a plane (e.g., an xy plane). As an example, an area of xy coordinates corresponding to the at least a part of the first wick 321 may be different from an area of xy coordinates corresponding to the at least a part of the second wick 322. Each of the at least a part of the first wick 321 and the at least a part of the second wick 322 on a three-dimensional space may be disposed on planes (e.g., planes parallel to a xy plane and having different z-axis) spaced apart from each other, based on the direction (e.g., the z-axis direction). In other words, an area occupied by the at least a part of the first wick 321 may have a different height from an area occupied by the at least a part of the second wick 322. As a non-limiting example, each of the at least a part of the first wick 321 and the at least a part of the second wick 322 may be disposed on the same plane (e.g., parallel to the xy plane) corresponding to the same height based on the direction (e.g., the z-axis direction).

In order to secure the sufficient moving path of steam in the limited thickness, the at least a part of the first wick 321 and the at least a part of the second wick 322 may be disposed in order not to overlap. For example, the first path portion 321b of the first wick 321 and the second path portion 322b of the second wick 322 may not overlap each other. For example, when viewed in a direction (e.g., a (+)z-axis direction), the first path portion 321b and the second path portion 322b of the second wick 322 may not overlap each other. The first path portion 321b of the first wick 321 and the second path portion 322b of the second wick 322 may be disposed in order not to overlap each other when viewed in a direction (e.g., a z-axis direction). For example, each of the first path portion 321b of the first wick 321 and the second path portion 322b of the second wick 322 may be disposed at different positions based on a plane (e.g., an xy plane). As an example, for refrigerant transmission to a direction (e.g., a (+)y-axis direction) from a bottom side of the electronic device 101 to a top side of the electronic device 101, each of the first path portion 321b and the second path portion 322b may have a longitudinal direction (e.g., the (+)y-axis direction). In other words, each of the first path portion 321b and the second path portion 322b may extend in the longitudinal direction. The first path portion 321b may have a longitudinal direction (e.g., the (+)y-axis direction) from the bottom side of the electronic device 101 to the top side of the electronic device 101. The second path portion 322b may have a longitudinal direction (e.g., the (+)y-axis direction) from the bottom side of the electronic device 101 to the top side of the electronic device 101. For example, the first path portion 321b may be disposed on a left side (e.g., a (−)x-axis direction) and the second path portion 322b may be disposed on a right side (e.g., a (+)x-axis direction). In a three-dimensional space, each of the first path portion 321b of the first wick 321 and the second path portion 322b of the second wick 322 may be disposed on planes (e.g., planes parallel to the xy plane and having different z axes) spaced apart from each other based on a direction (e.g., a z-axis direction). As a non-limiting example, each of the first path portion 321b of the first wick 321 and the second path portion 322b of the second wick 322 may be disposed on the same plane (e.g., parallel to the xy plane) corresponding to the same height based on the direction (e.g., the z-axis direction).

According to an embodiment, the first condensation portion 321c of the first wick 321 and the second condensation portion 322c of the second wick 322 may at least partially overlap each other. At the bottom side of the vapor chamber 220, steam may be liquefied and liquefied refrigerant may be absorbed into each wick. The first condensation portion 321c of the first wick 321 and the second condensation portion 322c of the second wick 322 may at least partially overlap so that the liquefied refrigerant may be evenly absorbed into the two wicks (e.g., the first wick 321, and the second wick 322).

In FIG. 3B, it is illustrated that the first condensation portion 321c of the first wick 321 and the second condensation portion 322c of the second wick 322 overlap each other, but embodiments of the present disclosure are not limited to the above examples. For example, in order to isolate heat dissipation for the display driver circuit 215 and heat dissipation for the processor 245, the first condensation portion 321c of the first wick 321 and the second condensation portion 322c of the second wick 322 may not overlap each other.

For example, as a non-limiting example, the first evaporation portion 321a of the first wick 321 and the second evaporation portion 322a of the second wick 322 may not overlap each other. For example, when viewed in a direction (e.g., a (+)z-axis direction), the first evaporation portion 321a and the second evaporation portion 322a of the second wick 322 may not overlap each other. The first evaporation portion 321a and the second evaporation portion 322a of the second wick 322 may be disposed at different positions on a plane (e.g., an xy plane). For effective heat dissipation, positions of two heat sources including the display driver circuit 215 and the processor 245 may be disposed at different positions based on the plane (e.g., the xy plane). On a three-dimensional space, the two heat sources may be disposed on plane (e.g., planes parallel to the xy plane and having different z-axis) s spaced apart from each other based on a direction (e.g., a z-axis direction). An area of xy-coordinates corresponding to one heat source on each plane may be different from an area of xy-coordinates corresponding to another heat source.

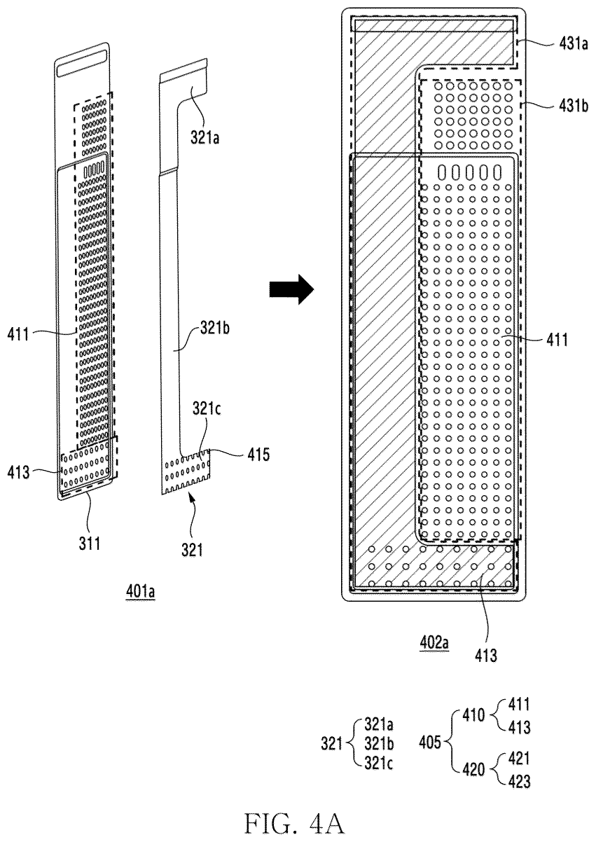

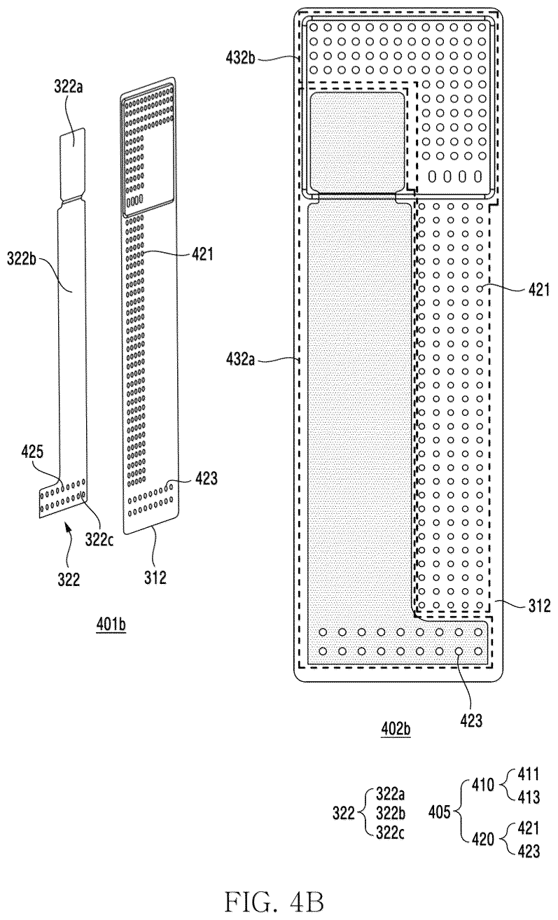

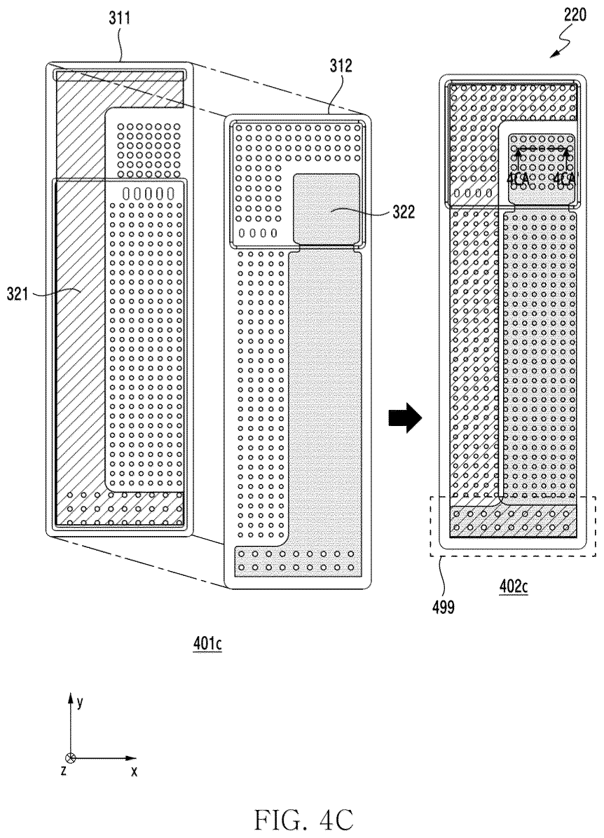

FIGS. 4A, 4B, and 4C indicate examples of components of a vapor chamber (e.g., a vapor chamber 220). Descriptions of FIGS. 3A and 3B may be referred to for each component of a vapor chamber 220. For example, the vapor chamber 220 may include a first wick 321 and a second wick 322. Non-limiting examples of the first wick 321 and the second wick 322 are shown in FIG. 3B. For the same descriptions, the same reference number may be used.

Referring to FIG. 4A, the vapor chamber 220 may include a first plate 311 receiving heat from a display driver circuit 215 and the first wick 321 attached to the first plate 311. An example 401a may indicate each of the first plate 311 and the first wick 321, and an example 402 a may indicate a shape in which the first wick 321 is attached to the first plate 311. The first wick 321 may include a first evaporation portion 321a, a first path portion 321b, and a first condensation portion 321c.

In order to prevent a part of a plate from being dented due to a difference in atmospheric pressure in the vapor chamber 220 and to secure a path through which steam moves, protruding portions 405 may be disposed between the first plate 311 and a second plate 312. According to an embodiment, the first plate 311 may have protruding portions 410. For example, the protruding portions 410 of the first plate 311 may correspond to protrusions formed on a side (e.g., a (-)z axis) of the first plate 311. The protruding portions 410 of the first plate 311 may be integrally formed with the first plate 311. According to an embodiment, the protruding portions 410 of the first plate 311 may be separate components coupled to the first plate 311. Each of the protruding portions 410 may be referred to as a boss or a support pillar. The first plate 311 may include a first wick area 431a on which the first wick 321 is disposed and a first support area 431b different from the first wick area 431a. The first plate 311 may have a first set 411 of protruding portions disposed on the first support area 431b. The first plate 311 may have a third set 413 of protruding portions disposed on a bottom side of the first wick area 431a.

The first condensation portion 321c of the first wick 321 may have holes 415 for protruding portions to reduce interference with the protruding portions included in the third set 413 of the protruding portions. The first condensation portion 321c of the first wick 321 may have a plurality of holes 415 corresponding to the protruding portions included in the third set 413. When the first wick 321 is attached to the first plate 311, the first path portion 321b of the first wick 321 may not include a separate hole since the first path portion 321b of the first wick 321 does not overlap pillars of the first plate 311. The protruding portions included in the first set 411 of the protruding portions may face the second plate 312 and contact the second wick 322. According to an embodiment, density of the protruding portions included in the first set 411 may be higher than density of the protruding portions included in the third set 413. Since the first support area 431b does not contact the protruding portions of the second plate 312 as exemplified in FIG. 4B, the protruding portions may be more densely disposed in the first support area 431b. As a non-limiting example, unlike illustration of FIG. 4A, the density of the protruding portions included in the first set 411 may be equal to or less than the density of the protruding portions included in the third set 413.

Referring to FIG. 4B, the vapor chamber 220 may include the second plate 312 receiving heat of a processor 245 and the second wick 322 attached to the second plate 312. An example 401b indicates each of the second plate 312 and the second wick 322. An example 402b indicates a shape in which the second wick 322 is attached to the second plate 312. The second wick 322 may include a second evaporation portion 322a, a second path portion 322b, and a second condensation portion 322c.

In order to prevent a part of a plate from being dented due to a difference in atmospheric pressure in the vapor chamber 220 and to secure a path through which steam moves, protruding portions 405 may be disposed between the first plate 311 and the second plate 312. According to an embodiment, the second plate 312 may have protruding portions 420. For example, the protruding portions 420 of the second plate 312 may correspond to protrusions formed on a side (e.g., a (+)z axis) of the second plate 312. The protruding portions 420 of the second plate 312 may be integrally formed with the second plate 312. According to an embodiment, the protruding portions 420 of the second plate 312 may be separate components coupled to the second plate 312. Each of the protruding portions 420 may be referred to as a boss or a support pillar. The second plate 312 may include a second wick area 432a on which the second wick 322 is disposed and a second support area 432b different from the second wick area 432a. The second plate 312 may have a second set 421 of protruding portions disposed on the second support area 432b. The second plate 312 may have a fourth set 423 of protruding portions disposed on a bottom side of the second wick area 432a.

The second condensation portion 322c of the second wick 322 may have holes 425 for protruding portions to reduce interference with the protruding portions included in the fourth set 423 of the protruding portions. The second condensation portion 322c of the second wick 322 may have a shape having a plurality of holes 425 corresponding to the protruding portions included in the fourth set 423. When the second wick 322 is attached to the second plate 312, the second path portion 322b of the second wick 322 may not include a separate hole since the second path portion 322b of the second wick 322 does not overlap pillars of the second plate 312. The protruding portions included in the second set 421 of the protruding portions may face the first plate 311 and contact the first wick 321. According to an embodiment, density of the protruding portions included in the second set 421 may be higher than density of the protruding portions included in the fourth set 423. Since the second support area 432b does not contact the protruding portions of the second plate 312 as exemplified in FIG. 4A, the protruding portions may be more densely disposed in the second support area 432b. As a non-limiting example, unlike illustration of FIG. 4A, the density of the protruding portions included in the second set 421 may be equal to or less than the density of the protruding portions included in the fourth set 423.

Referring to FIG. 4C, the vapor chamber 220 may include the first plate 311 receiving heat of the display driver circuit 215 and the first wick 321 attached to the first plate 311. The vapor chamber 220 may include the second plate 312 receiving heat of the processor 245 and the second wick 322 attached to the second plate 312. The first plate 311 to which the first wick 321 is attached and the second plate 312 to which the second wick 322 is attached may be coupled. For example, the first plate 311 and the second plate 312 may be coupled in a direction (e.g., a z-axis direction). An internal space may be formed through coupling of the first plate 311 and the second plate 312. The first wick 321 may be attached to an inner side of the first plate 311 in the internal space. The second wick 322 may be attached to an inner side of the second plate 312 on the internal space. The internal space may be used as a moving path of steam.

Since the two wicks (e.g., the first wick 321, and the second wick 322) are disposed on different plates, a structure (e.g., protruding portions) for supporting the plates in the internal space may also be disposed by being divided into the two plates. For example, the first wick 321 may be attached to the first plate 311 and supported through protruding portions of the second plate 312 (e.g., the second set 421 of the protruding portions and the fourth set 423 of the protruding portions). For example, the second wick 322 may be attached to the second plate 312 and supported through protruding portions (e.g., the first set 411 of the protruding portions, the third set 413 of the protruding portions) of the first plate 311.

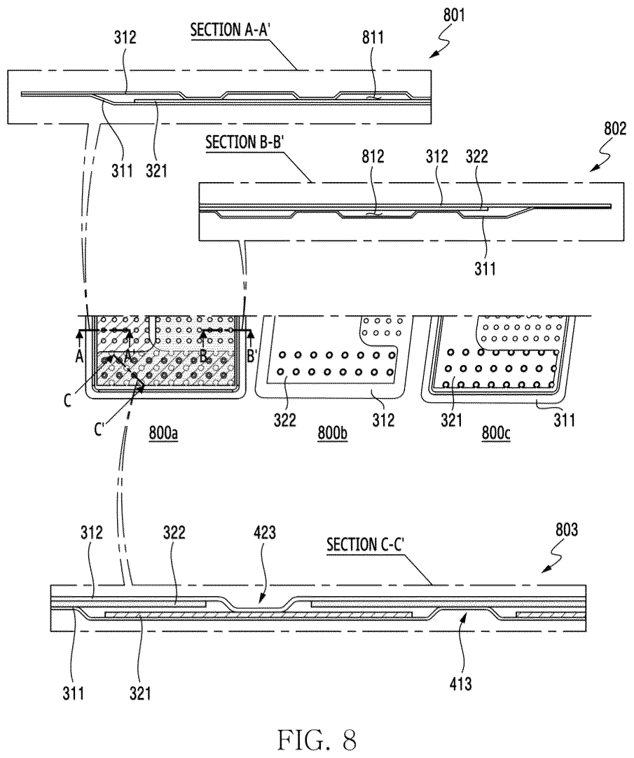

A bottom side 499 of the vapor chamber 220 may be an area in which steam is liquefied, and liquefied refrigerant may be absorbed into the first wick 321 and/or the second wick 322. The first condensation portion 321c of the first wick 321 and the second condensation portion 322c of the second wick 322 may be disposed to overlap each other in order to be evenly absorbed into the two wicks. When viewed from a direction (e.g., a z-axis direction), the two wicks may be arranged to overlap. At the bottom side of the vapor chamber 220, for support of the two wicks, protruding portions included in the third set 413 of the protruding portions and protruding portions included in the fourth set 423 of the protruding portions may be disposed together. The first wick 321 may include the holes 415 corresponding to the protruding portions included in the third set 413 such that the protruding portions included in the fourth set 423 do not influence the first wick 321 while supporting the second wick 322. The second wick 322 may include the holes 425 corresponding to the protruding portions included in the fourth set 423 so that the protruding portions included in the fourth set 423 do not influence the second wick 322 while supporting the first wick 321. For overlapping the first wick 321 and the second wick 322 at the bottom side 499 of the vapor chamber 220, descriptions of FIG. 8 may be referred to.

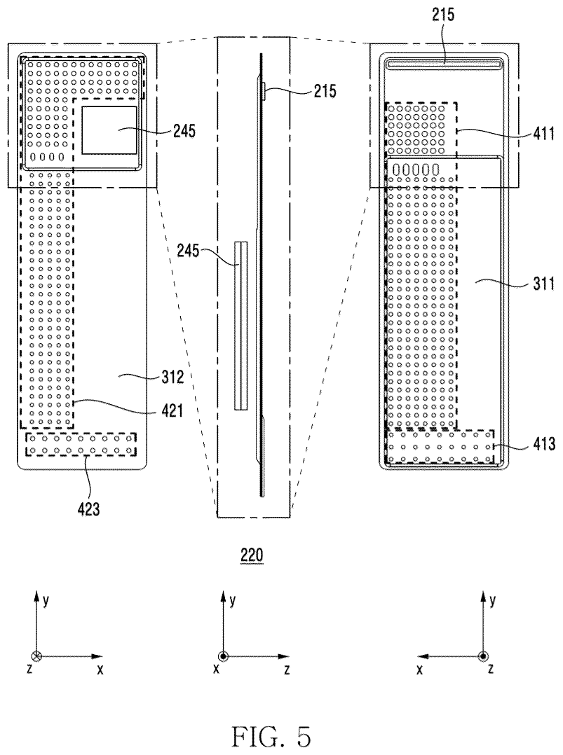

FIG. 5 indicates an example of a disposition of a display driver circuit (e.g., a display driver circuit 215), at least one processor (e.g., a processor 245), and a vapor chamber (e.g., a vapor chamber 220). For the same descriptions, the same reference number may be used.

Referring to FIG. 5, the vapor chamber 220 may be disposed between a display driver circuit 215 and the processor 245. The vapor chamber 220 may include a first plate 311 and a second plate 312. The first plate 311 may have a first side facing a direction (e.g., a (+)z-axis direction). The display driver circuit 215 may be disposed on the first side. The first plate 311 may have protruding portions (e.g., protruding portions included in a first set 411 and protruding portions included in a third set 413) facing the direction (e.g., the (+)z-axis direction). For example, the protruding portions may correspond to protruding protrusions for supporting for a second wick 322. The second plate 312 may have a second side facing a direction (e.g., a (−)z-axis direction). The processor 245 may be disposed on the second side. The second plate 312 may have protruding portions (e.g., protruding portions included in a second set 421 and protruding protrusions included in a fourth set 423) facing the direction (e.g., the (−)z-axis direction). For example, the protruding portions may correspond to protruding protrusions for supporting for the first wick 321.

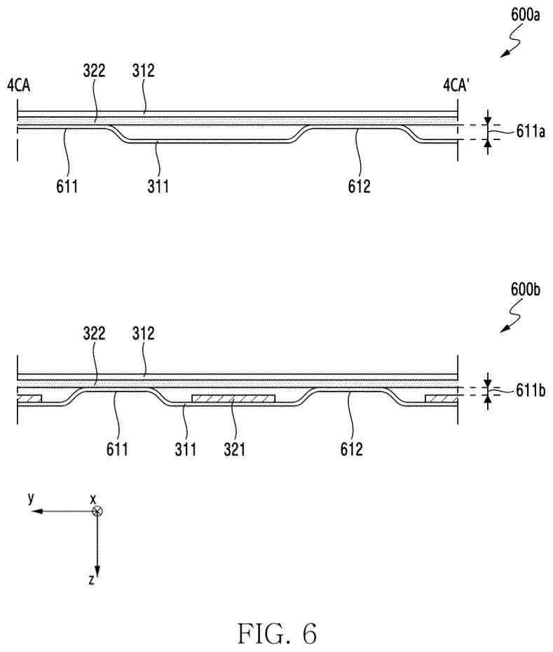

FIG. 6 indicates an example of a vapor chamber (e.g., a vapor chamber 220) including a first wick (e.g., a first wick 221) and a second wick (e.g., a second wick 222). For the same descriptions, the same reference number may be used.

Referring to FIG. 6, an example 600a indicates a structure (e.g., a section 4CA-4CA′) in which one wick is disposed in a stacking direction (e.g., a z-axis direction) between two plates (e.g., a first plate 311, and a second plate 312) of the vapor chamber 220. The first plate 311 may have protruding portions (e.g., a protruding portion 611 and a protruding portion 612). The protruding portion of the first plate 311 may be disposed to support a second wick 322 attached to the second plate 312. A space excluding protruding portions between a first wick 321 and the second plate 312 may be used as a moving path for gas. For example, a space corresponding to a first interval 611 a in the example 600a may be used as the moving path for the gas. An example 600b may indicate a structure in which two wicks are disposed in a stacking direction (e.g., a z-axis direction) between two plates (e.g., a first plate 311 and a second plate 312) of the vapor chamber 220. The first plate 311 may have protruding portions (e.g., the protruding portion 611 and the protruding portion 612). The protruding portions of the first plate 311 may be disposed to support the second wick 322 attached to the second plate 312. The first wick 321 may be disposed in a space other than the protruding portion of the first plate 311. For example, as the first wick 321 and the second wick 322 are positioned together in the space between the protruding portions, a moving path of the gas may be narrowed. In the example 600b, a space corresponding to a second interval 611b may be used as the moving path for the gas.

In a case that it is difficult to move the gas, thermal resistance in the vapor chamber 220 may increase. In order to secure heat dissipation performance of the vapor chamber 220, it may be required to secure a sufficient interval. For example, in a case that a wick is entirely disposed on each of a second side of the first plate 311 and a second side of the second plate 312 in a limited thickness, a moving path of steam may be narrowed due to a thickness of the wick. Since the moving path of steam of the gas is narrowed, the thermal resistance may increase. In order to secure the sufficient moving path of the gas in the limited thickness, at least a part of the first wick 321 and at least a part of the second wick 322 may each be disposed at different positions on a plane (e.g., an xy plane).

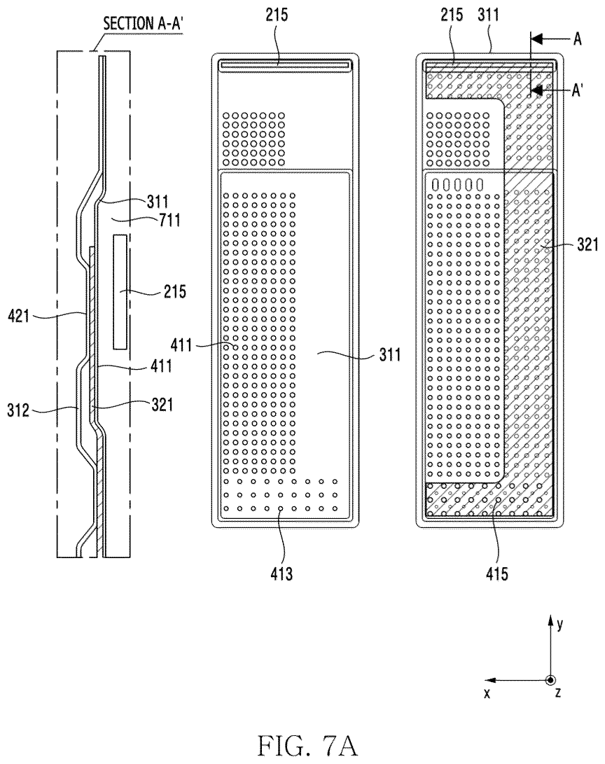

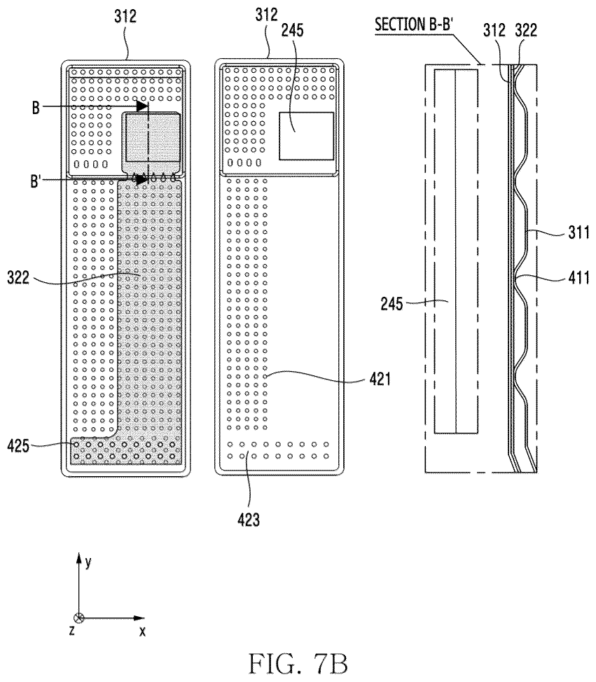

FIGS. 7A and 7B indicate examples of a vapor chamber (e.g., a vapor chambers 220) of plates (e.g., a first plate 311, and a second plate 312) having protruding portions. For the same descriptions, the same reference number may be used.

Referring to FIG. 7A, an electronic device 101 may include the vapor chamber 220. The vapor chamber 220 may include a first plate 311 and a first wick 321 attached to the first plate 311. A display driver circuit 215 may be disposed on a first side (e.g., a side facing a (+)z axis) of the first plate 311. According to an embodiment, for the display driver circuit 215, the first plate 311 may include a recess portion 711 dented in a direction (e.g., a (+)z-axis direction). In order to reduce an influence of thickness increase due to the display driver circuit 215, the display driver circuit 215 may be disposed over the recess portion 711. The display driver circuit 215 may be disposed over an area corresponding to the recess portion 711 among the first sides of the first plate 311. The first wick 321 may be in contact with a second side (e.g., a side facing a (−)z axis) of the first plate 311. Protruding portions may be formed on the second side of the first plate 311 in a direction (e.g., a (-z)-axis direction) facing an inner side of the first plate 311. For example, the first plate 311 may have protruding portions included in a first set 411 of protruding portions and protruding portions included in the third set 413 of protruding portions. In order to support the first wick 321 attached to the first plate 311, a second plate 312 may include protruding portions (e.g., a second set 421 of protruding portions and a fourth set 423 of protruding portions) formed in a direction facing an inner side of the second plate 312.

In FIG. 7A, the first plate 311 in which a recess portion for the display driver circuit 215 is formed is illustrated, but embodiments of the present disclosure are not limited to the above example embodiment. Even if an area in which the display driver circuit 215 is disposed on the first side of the first plate 311 is a flat area without a separate recess portion, it may be understood as an embodiment of the present disclosure.

Referring to FIG. 7B, the electronic device 101 may include the vapor chamber 220. The vapor chamber 220 may include the second plate 312 and a second wick 322 attached to the second plate 312. A processor 245 may be disposed on a first side (e.g., a side facing a (-)z axis) of the second plate 312. The second wick 322 may be in contact with a second side (e.g., a side facing a (+)z axis) of the second plate 312. Protruding portions may be formed on the second side of the second plate 312 in a direction (e.g., a (+z)axis direction) facing an inner side of the second plate 312. For example, the second plate 312 may have protruding portions included in a second set 421 of protruding portions and protruding portions included in the fourth set 423 of protruding portions. In order to support the second wick 322 attached to the second plate 312, the first plate 311 may include protruding portions (e.g., the first set 411 of the protruding portions and the third set 413 of the protruding portions) formed in a direction facing an inner side of the first plate 311.

As a non-limiting example, for the processor 245, the second plate 312 may include a recess portion dented in a direction (e.g., in a (-)z-axis direction). In order to reduce an influence of a thickness increase due to a stacked structure including the processor 245, the processor 245 may be disposed over the recess portion. the processor 245 may be disposed over an area corresponding to the recess portion among the first sides of the second plate 312.

FIG. 8 indicates an example of an overlapping structure of a first wick (e.g., a first wick 221) and a second wick (e.g., a second wick 222). For the same descriptions, the same reference number may be used.

Referring to FIG. 8, an electronic device 101 may include a first plate 311, a second plate 312, a first wick 321, and a second wick 322. An example 800a indicates a structure in which the first plate 311 to which the first wick 321 is attached and the second plate 312 to which the second wick 322 is attached are coupled. An example 800b indicates the second plate 312 to which the second wick 322 is attached. An example 800c indicates the first plate 311 to which the first wick 321 is attached.

Referring to a first cross section 801 in the example 800a, the first wick 321 may be disposed on the first plate 311. Steam may move through a space 811 formed between the first wick 321 and the second plate 312. Referring to a second cross section 802 in the example 800a, the second wick 322 may be disposed on the second plate 312. Steam may move through a space 812 formed between the second wick 322 and the first plate 311. Referring to a third cross section 803 in the example 800a, the first wick 321 and the second wick 322 may overlap at a bottom side (e.g., a first condensation portion 321c or the second condensation portion 322c) of the vapor chamber 220. The first wick 321 may be disposed on the first plate 311. The second wick 322 may be disposed on the second plate 312. For support of the second wick 322, a protruding portion (e.g., a protruding portion included in a third set 413 of protruding portions) of the first plate 311 may be in contact with the second wick 322. For support of the first wick 321, a protruding portion (e.g., a protruding portion included in a fourth set 423 of protruding portions) of the second plate 312 may be in contact with the first wick 321. Liquefied refrigerant may be positioned in a space between the first wick 321 and the second wick 322. The refrigerant may be absorbed into the first wick 321 and/or the second wick 322. The absorbed refrigerant may be transmitted to a first evaporation portion 321a and/or a second evaporation portion 322a.

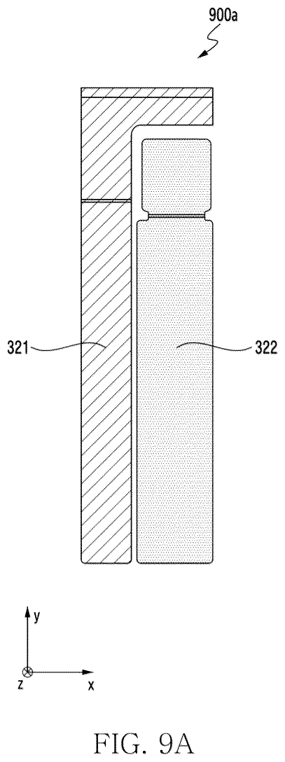

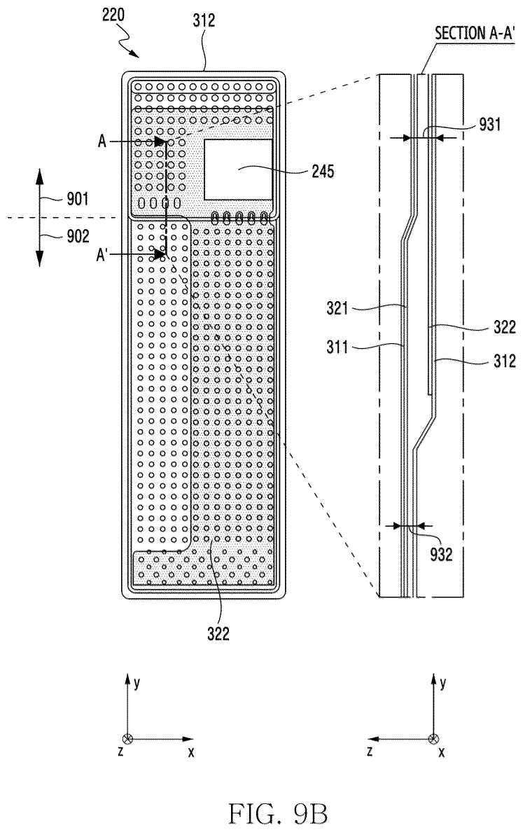

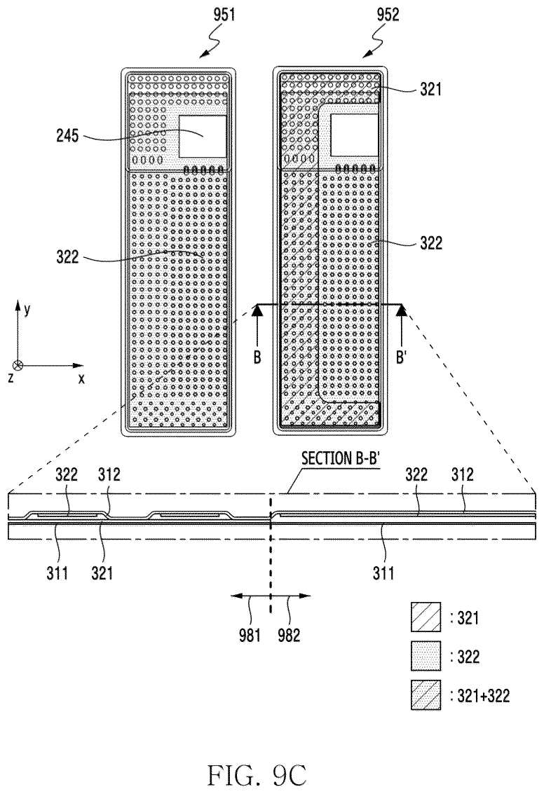

FIGS. 9A, 9B, and 9C indicate examples of a shape of a second wick (e.g., a second wick 322) for at least one processor (e.g., a processor 245). In a case that refrigerant liquefied in a vapor chamber 220 is difficult to move near a heat source (e.g., a display driver circuit 215 or the processor 245), thermal resistance of the vapor chamber 220 increases. In order to increase heat dissipation performance of the vapor chamber 220, it may be required to secure sufficient performance of a wick. For the same descriptions, the same reference number may be used.

Referring to FIG. 9A, in an example 900a, the second wick 322 may have a shape that does not overlap a first wick 321 at all. For example, the first wick 321 may include a first evaporation portion 321a, a first path portion 321b, and a first condensation portion 321c. The second wick 322 may include a second evaporation portion 322a, a second path portion 322b, and a second condensation portion 322c. Unlike formation exemplified in FIGS. 3B to 8, the first condensation portion 321c and the second condensation portion 322c may not overlap each other.

Referring to FIG. 9B, the vapor chamber 220 may include a top side portion 901 and a bottom side portion 902 based on a reference line (e.g., a line parallel to an x-axis). The top side portion 901 and the bottom side portion 902 may be divided by a difference in height (e.g., a coordinate in a y-axis). The top side portion 901 of the vapor chamber 220 may correspond to the second evaporation portion 322a of the second wick 322. The bottom side portion 902 of the vapor chamber 220 may correspond to the second path portion 322b and the second condensation portion 322c of the second wick 322. According to an embodiment, the vapor chamber 220 may have a step. In the top side portion 901, a width 931 between the first plate 311 and the second plate 312 may be a first value. In the bottom side portion 902, a width 932 between the first plate 311 and the second plate 312 may be a second value. The first value may be wider than the second value.

In a case that the two wicks (e.g., the display driver circuit 215 and the processor 245) are disposed in order not to simply overlap to dissipate heat from two components, cross-sectional extent of each wick may be decreased. Decrease in the cross-sectional extent of the wick may decrease a heat dissipation effect. In order to increase the heat dissipation effect on the processor 245, a part of the second wick 322 may be disposed to overlap the first wick 321. A thickness (e.g., the width 931) of the top side portion 901 of the vapor chamber 220 is greater than a thickness (e.g., the width 932) of the bottom side portion 902. Accordingly, the wo wicks may be disposed in an internal space between the first plate 311 and the second plate 312. An influence due to the two wicks in the top side portion 901 may be smaller than an influence due to the two wicks in the bottom side portion 902. According to an embodiment, the second evaporation portion 322a of the second wick 322 may overlap the first evaporation portion 321a of the first wick 321. Unlike formation exemplified in FIGS. 3B to 8, the second evaporation portion 322a of the second wick 322 may expand on a plane. For example, the second evaporation portion 322a of the second wick 322 may extend in a direction (e.g., a (-)x-axis direction). As a non-limiting example, the second wick 322 may be formed to occupy all areas except the display driver circuit 215 and the processor 245 in the top side portion 901.

Referring to FIG. 9C, the vapor chamber 220 may include a left portion 981 and a right portion 982 based on a reference line (e.g., a line parallel to a y-axis). The left portion 981 and the right portion 982 may be divided by a difference (e.g., a coordinate in an x-axis) in distance. According to an embodiment, instead of the first wick 321 and the second wick 322 being divided into left and right sides, the first wick 321 may be disposed in the left portion 981, and the second wick 322 may be disposed in both the left portion 981 and the right portion 982. For example, the second wick 322 may be disposed to occupy all areas of a plane (e.g., an xy plane) of the vapor chamber 220. The first wick 321 and the second wick 322 may be disposed on the left portion 981 of the vapor chamber 220. A space between the first wick 321 and the second wick 322 may be formed in the left portion 981. The second wick 322 may be disposed on the right portion 982 of the vapor chamber 220. In the right portion 982, steam may move in a space between the second wick 322 and the first plate 311.

While reducing a width (e.g., an x-axis length in the xy plane) of the first wick 321 for the display driver circuit 215 with relatively low heat generation, a width of the second wick 322 for the processor 245 with relatively high heat generation may increase. In addition, since a width in an internal space is secured due to absence of the first wick 321 in the right portion 382, steam may move. Since the second wick 322 may maximize an extent of a cross section (e.g., the xy plane) of a vapor chamber, heat dissipation performance for the processor 245 may be increased.

In FIGS. 3A to 9C, a structure in which the first plate 311 and the first wick 321 for the display driver circuit 215, and the second plate 312 and the second wick 322 for the processor 245 are disposed in one vapor chamber 220 has been described. High heat dissipation performance may be provided in a limited space as a heat dissipation structure for two components (e.g., the display driver circuit 215 and the processor 245) is used through one vapor chamber 220 instead of including a separate vapor chamber for each component. For example, in a case that two vapor chambers are provided for the two components, an internal volume in the actual vapor chamber decreases due to a welding line for each vapor chamber and a separation distance between the two vapor chambers. Therefore, an efficient heat dissipation function for the two components (e.g., the display driver circuit 215 and the processor 245) may be provided through a structure of one vapor chamber 220 in a limited space.

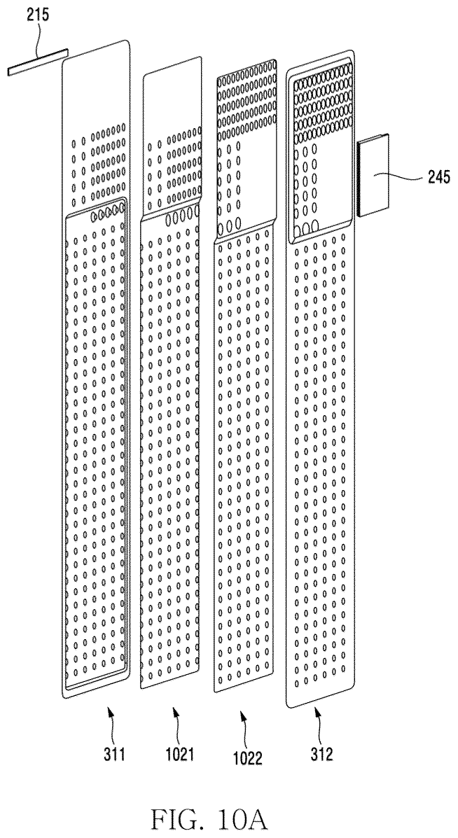

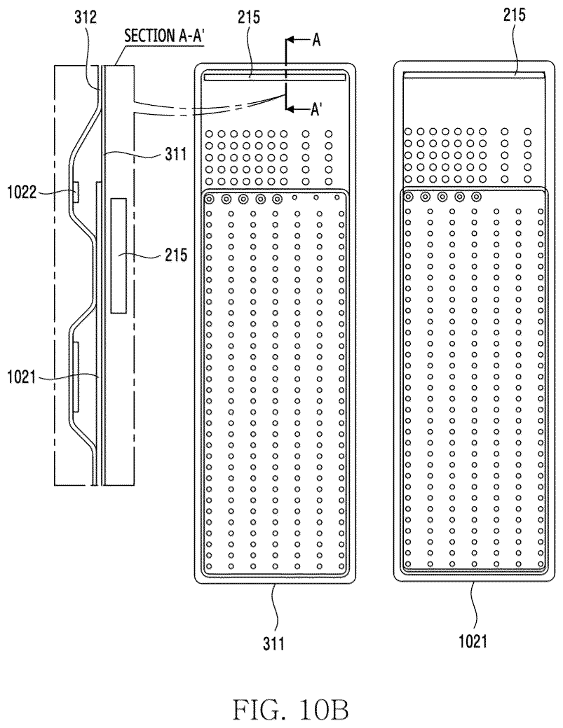

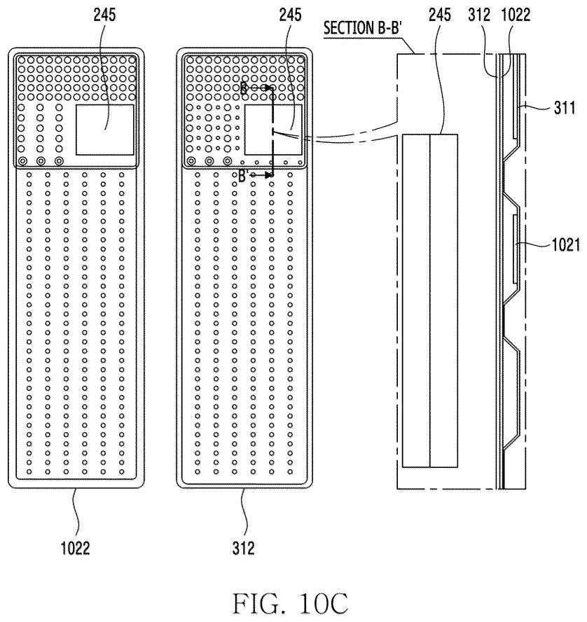

FIGS. 10A, 10B, and 10C indicate examples of components of a vapor chamber (e.g., a vapor chamber 220). For the same descriptions, the same reference number may be used.

Referring to FIG. 10A, the vapor chamber 220 may be disposed between a display driver circuit 215 and a processor 245. The vapor chamber 220 may include a first plate 311, a second plate 312, a first wick 1021, and a second wick 1022. The first plate 311 may include a first side (e.g., a side facing a (+)z-axis) and a second side opposite to the first side (e.g., a side facing a (-)z-axis). The second plate 312 may include a first side (e.g., a side facing a (-)z-axis) and a second side (e.g., a side facing a (+)z-axis) opposite to the first side.

According to an embodiment, the first wick 1021 and the second wick 1022 may overlap. Each of the first wick 1021 and the second wick 1022 may have a shape occupying all areas of the vapor chamber 220. In a case that a thickness of the vapor chamber 220 is a thickness in which a space in which steam moves is secured even if the two wicks are disposed, the wicks may be disposed over the entire area of the vapor chamber 220 on each of the first plate 311 and the second plate 312. The first plate 311 may have protruding portions for supporting the second wick 1022. The protruding portions may be disposed over the entire area of the vapor chamber 220. The first wick 1021 may have holes corresponding to the protruding portions of the first plate 311. The second plate 312 may have protruding portions for supporting the first wick 1021. The protruding portions may be disposed over the entire area of the vapor chamber 220. The second wick 1022 may have holes corresponding to the protruding portions of the second plate 312.

Referring to FIG. 10B, a first wick 1021 may be attached to a side of the first plate 311. The first wick 1021 may include the holes corresponding to the protruding portions of the first plate 311. Positions of the holes in the first wick 1021 may correspond to positions of the protruding portions in the first plate 311. Likewise, positions of the holes in the second wick 1022 may correspond to positions of the protruding portions in the second plate 312. In a case that a hole is drilled in an area (hereinafter, a heat source area) corresponding to a portion in which the display driver circuit 215 is disposed among the first wick 1021, an amount of refrigerant vaporized may be reduced since a wick extent may be reduced. Therefore, a hole may not be drilled in the heat source area among the first wick 1021. The second plate 312 may have a protruding portion to support the heat source area of the first wick 1021. The protruding portion of the second plate 312 may be in contact with the heat source area of the first wick 1021.

Referring to FIG. 10C, a second wick 1022 may be attached to a side of the second plate 312. The second wick 1022 may include the holes corresponding to the protruding portions of the second plate 312. Positions of the holes in the second wick 1022 may correspond to positions of the protruding portions in the second plate 312. Likewise, positions of the holes in the first wick 1021 may correspond to positions of the protruding portions in the first plate 311. In a case that a hole is drilled in an area (hereinafter, a heat source area) corresponding to a portion in which the processor 245 is disposed among the second wick 1022, an amount of refrigerant vaporized may be reduced since a wick extent may be reduced. Therefore, a hole may not be drilled in the heat source area among the second wick 1022. The first plate 311 may have a protruding portion to support the heat source area of the second wick 1022. The protruding portion of the first plate 311 may be in contact with the heat source area of the second wick 1022.

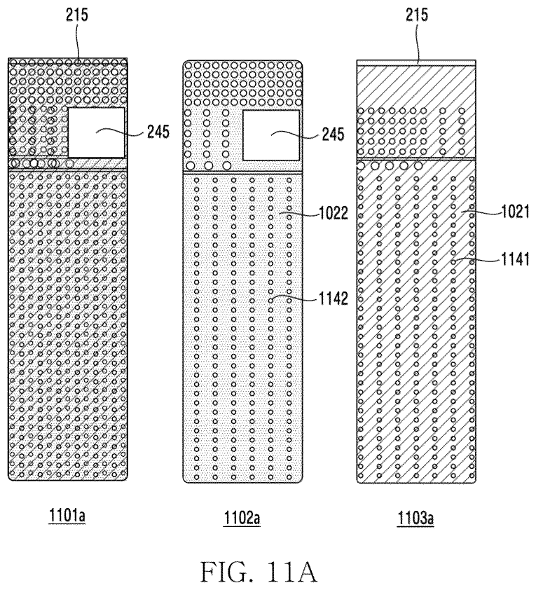

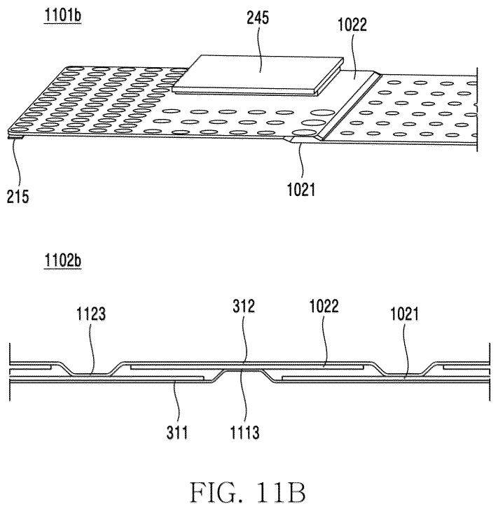

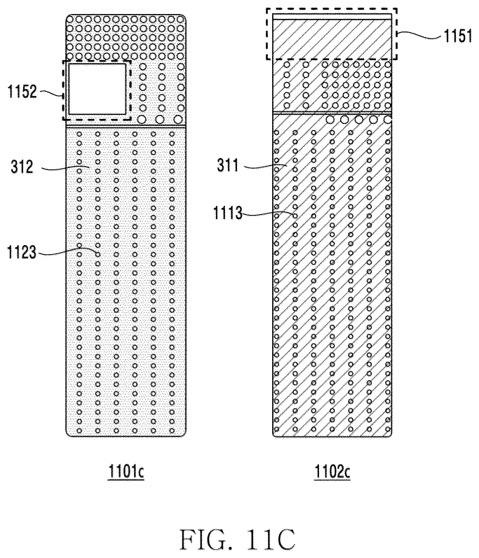

FIGS. 11A, 11B, and 11C indicate examples of an overlapping structure of the first wick (e.g., a first wick 1021) and the second wick (e.g., a second wick 1022). For the same descriptions, the same reference number may be used.

Referring to FIG. 11A, an example 1101a indicates a vapor chamber 220 in which a first wick 1021 for a display driver circuit 215 and a second wick 1022 for a processor 245 overlap. An example 1101b indicates the second wick 1022 for the processor 245. The second wick 1022 may include holes. The holes of the second wick 1022 may be referred to as a second set 1142 of the holes. The holes of the second set 1142 may correspond to protruding portions of a second plate 312 contacted by the second wick 1022. An example 1101c indicates the first wick 1021 for the display driver circuit 215. The first wick 1021 may include holes. The holes of the first wick 1021 may be referred to as a first set 1141 of the holes. The holes of the first set 1141 may correspond to protruding portions of a first plate 311 contacted by the first wick 1021.

According to an embodiment, the holes included in the first set 1141 and the holes included in the second set 1142 in the vapor chamber 220 may not overlap each other. For example, when the vapor chamber 220 is viewed in a direction, the holes included in the first set 1141 and the holes included in the second set 1142 may not overlap each other. The holes included in the first set 1141 may be divided into arrangements in a direction from a top side to a bottom side of the electronic device 101. The holes included in the second set 1142 may be divided into arrangements in a direction from a top side to a bottom side of the electronic device 101. According to an embodiment, the arrangements of the first set 1141 and the arrangements of the second set 1142 may be alternately disposed.

Referring to FIG. 11B, the example 1101b indicates the vapor chamber 220 in which a first wick 1021 and a second wick 1022 disposed between the display driver circuit 215 and the processor 245 are overlapped. The example 1102b indicates a cross section of the vapor chamber 220. Referring to FIG. 11C, the example 1101C indicates the second plate 312 contacting the second wick 1022. An example 1102C indicates the first plate 311 contacting the first wick 1021. The first plate 311 may include protruding portions. The protruding portions of the first plate 311 may be referred to as a first set 1113 of the protruding portions. The protruding portions included in the first set 1113 may correspond to holes included in the first set 1141 in the first wick 1021. The second plate 312 may include protruding portions. The protruding portions of the second plate 312 may be referred to as a second set 1123 of the protruding portions. The protruding portions included in the second set 1123 may correspond to holes included in the second set 1142 in the second wick 1022. For support of the second wick 1022, a protruding portion (e.g., a protruding portion included in the first set 1113 of the protruding portions) of the first plate 311 may contact the second wick 1022. For the support of the first wick 1021, a protruding portion of the second plate 312 (e.g., a protruding portion included in the second set 1123 of the protruding portions) may contact the first wick 321.

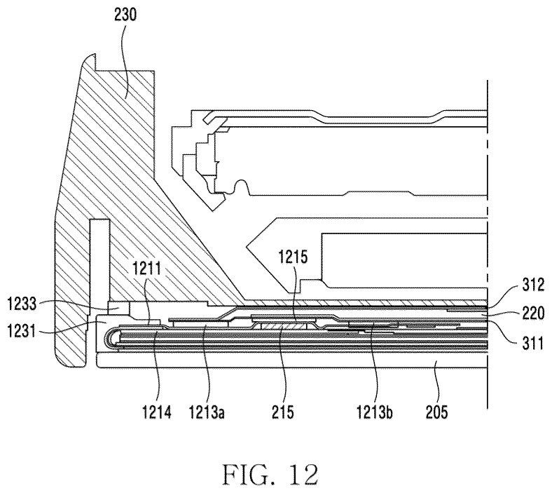

FIG. 12 indicates an example of a disposition of a display driver circuit (e.g., a display driver circuit 215) for heat dissipation. For the same descriptions, the same reference number may be used.

Referring to FIG. 12, an electronic device 101 may include a plurality of components. For example, the electronic device 101 may include a display panel 205, the display driver circuit 215, and/or a metal frame 230. For example, the electronic device 101 may include a vapor chamber 220. The vapor chamber 220 may include a first plate 311 and a second plate 312. The first plate 311 and the second plate 312 may be coupled to form an internal volume. The electronic device 101 may include components for a display. For example, the electronic device 101 may include a shielding sheet 1211 for the display driver circuit 215, a support portions 1213a or 1213b for preventing damage to the display driver circuit 215, a substrate 1214 connected to the display panel 205, a liquid TIM 1215 for the display driver circuit 215, a molding part 1231 for protecting a bending portion of the display panel 205, and/or a bonding portion 1233 for waterproofing components related to the display.

According to an embodiment, the electronic device 101 may include a disposition structure in which heat generated from the display driver circuit 215 is transmitted to the vapor chamber 220. The display driver circuit 215 disposed on the substrate 1214 may be covered with a shielding sheet 1211. The shielding sheet 1211 and the liquid TIM 1215 may be in contact with each other. The TIM 1215 may be in contact with the first plate 311 of the vapor chamber 220. Heat generated by the display driver circuit 215 may be transmitted to the vapor chamber 220 through the shielding sheet 1211 and the liquid TIM 1215. The heat of the display driver circuit 215 may be dissipated through the vapor chamber 220.

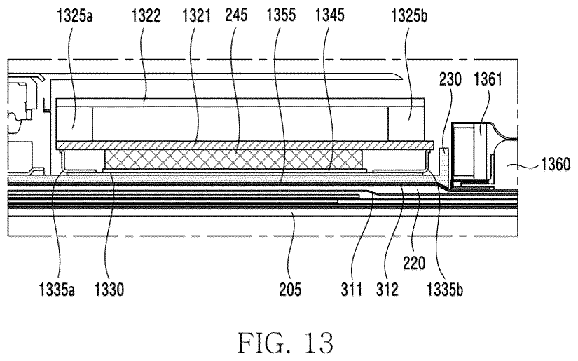

FIG. 13 indicates an example of a disposition of at least one processor (e.g., a processor 245) for heat dissipation. For the same descriptions, the same reference number may be used.

Referring to FIG. 13, an electronic device 101 may include a plurality of components. For example, the electronic device 101 may include a display panel 205, a metal frame 230, a battery cell 1360, and/or a protection circuit module (PCM) assembly 1361. For example, the electronic device 101 may include a vapor chamber 220. The vapor chamber 220 may include a first plate 311 and a second plate 312. The first plate 311 and the second plate 312 may be coupled to form an internal volume. A tape 1355 for the vapor chamber 220 may be disposed between the metal frame 230 and the vapor chamber 220. The electronic device 101 may include components for the processor 245. The electronic device 101 may include PCBs (e.g., a first PCB 1321 and a second PCB 1322) and/or interposer 1325a or 1325b for the processor 245. The electronic device 101 may include a heat dissipation sheet 1330 for electromagnetic shielding, a shield can 1335a or 1335b for the processor 245, and/or a TIM 1345 for the processor 245.

According to an embodiment, the electronic device 101 may include a disposition structure in which heat generated by the processor 245 is transmitted to the vapor chamber 220. The processor 245 may be disposed on the first PCB 1321. The processor 245 may contact the TIM 1345. The TIM 1345 may contact the heat dissipation sheet 1330, and the heat dissipation sheet 1330 may contact the metal frame 230. The metal frame 230 may be connected to the vapor chamber 220 through a tape 1355. The heat generated by the processor 245 may be transmitted to the vapor chamber 220 through the TIM 1345, the heat dissipation sheet 1330, the metal frame 230, and the tape 1355.

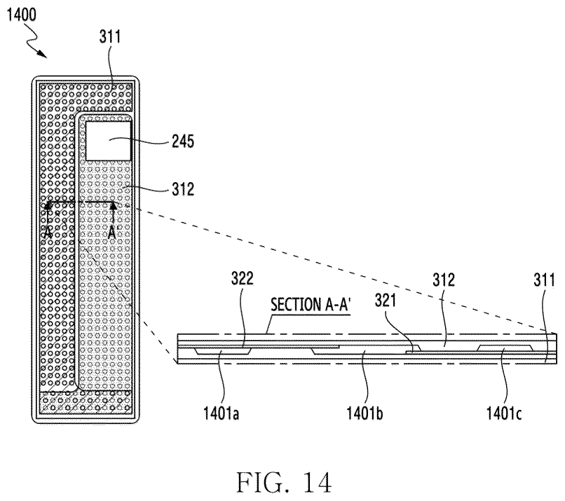

FIG. 14 indicates an example of a vapor chamber (e.g., a vapor chamber 220) using an etching method. For the same descriptions, the same reference number may be used.

Referring to FIG. 14, an electronic device 101 may include the vapor chamber 220. The vapor chamber 220 may include a first plate 311 and a second plate 312. The vapor chamber 220 may be formed in various ways. For example, the vapor chamber 220 may be manufactured through a press process on metal plates (e.g., the first plate 311, and the second plate 312). For example, as in an example 1400, the vapor chamber 220 may be formed by a method of etching a metal structure. For example, an internal space (e.g., a space 1401a, a space 1401b, or a space 1401c) may be formed between the first plate 311 and the second plate 312 through etching. A first wick 321 may be attached to the first plate 311 in the internal space. A second wick 322 may be attached to the second plate 312.

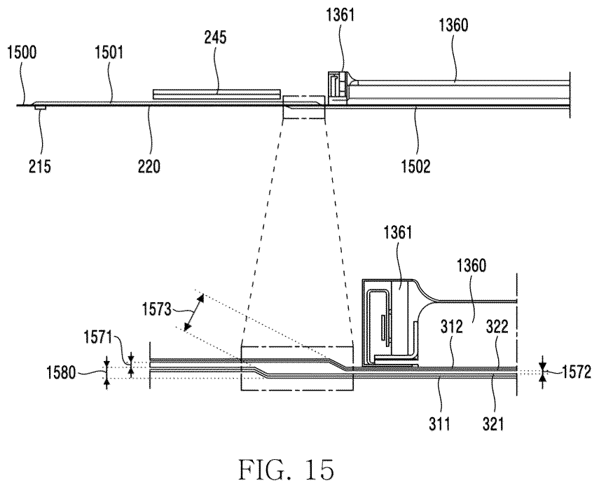

FIG. 15 indicates an example of a vapor chamber (e.g., a vapor chamber 220) of a curved shape. For the same descriptions, the same reference number may be used.

Referring to FIG. 15, a vapor chamber 220 may have a curved shape. For example, the vapor chamber 220 may include a curved portion. In order to describe the curved shape of the vapor chamber 220, a base plane 1500 may be defined. The vapor chamber 220 may include a top side portion 1501 and a bottom side portion 1502 based on the base plane 1500. The vapor chamber 220 may include a first plate 311, a second plate 312, a first wick 321, and a second wick 322. According to an embodiment, in a case of welding the first plate 311 and the second plate 312 of the vapor chamber 220, sides to be welded may coincide with the base plane 1500 in both the top side portion 1501 and the bottom side portion 1502. As a portion to which the first plate 311 and the second plate 312 are welded is positioned on the same plane (e.g., the base plane 1500) in each of the top side portion 1501 and the bottom side portion 1502, a decrease in yield may be reduced.

The processor 245 may be disposed over the top side portion 1501, and a display driver circuit 215 may be disposed under the top side portion 1501. Battery-related components (e.g., a battery cell 1360 and/or a protection circuit module (PCM) assembly 1361) may be disposed over the bottom side portion 1502 of the vapor chamber 220. An area (hereinafter, an overlapping area) in which the top side portion 1501 and the bottom side portion 1502 overlap may include a portion where the components of the vapor chamber 220 are curved. According to an embodiment, the display driver circuit 215 may be disposed closer to a top side of an electronic device 101 than to a bottom side of the electronic device 101. For disposition of the display driver circuit 215 and circuitry (e.g., FPCB) connected to the display driver circuit 215, a portion (e.g., the top side portion 1501) of the vapor chamber 220 may be disposed over the base plane 1500. As a distance between the vapor chamber 220 and the processor 245 increases, thermal resistance in heat transmission path of the processor 245 may decrease. In order to increase a capacity of a battery, a portion (e.g., the bottom side portion 1502) of the vapor chamber 220 may be disposed under the base plane 1500. Since the vapor chamber 220 protrudes up and down based on the base plane 1500, the vapor chamber 220 may have a step 1580.

The first plate 311 may include a first flat portion, a second flat portion, and a first inclined portion between the first flat portion and the second flat portion. The second plate 312 may include a third flat portion, a fourth flat portion, and a second inclined portion between the third flat portion and the fourth flat portion. A thickness 1571 of an internal space of the vapor chamber 220 in the top side portion 1501 may be a first value h1. For example, a distance between the first flat portion and the third flat portion may be the first value h1. A thickness 1572 of an internal space of the vapor chamber 220 in the bottom side portion 1502 may be a second value h2. For example, a distance between the second flat portion and the fourth flat portion may be the second value h2. In order to form a moving path of steam of the vapor chamber 220, the top side portion 1501 and the bottom side portion 1502 may overlap. A width 1573 may be a third value d in an area (i.e., the overlapping area) in which the top side portion 1501 and the bottom side portion 1502 overlap with each other based on the base plane 1500. According to an embodiment, in order to reduce a bottleneck in the overlapping area, the width 1573 in the overlapping area may be greater than each of the thickness 1571 of the internal space in the top side portion 1501 and the thickness 1572 of the internal space in the bottom side portion 1502. For example, the width d between the first inclined portion and the second inclined portion may be wider than a distance h1 between the first flat portion and the third flat portion. For example, the width d between the first inclined portion and the second inclined portion may be wider than the distance h2 between the second flat portion and the fourth flat portion.

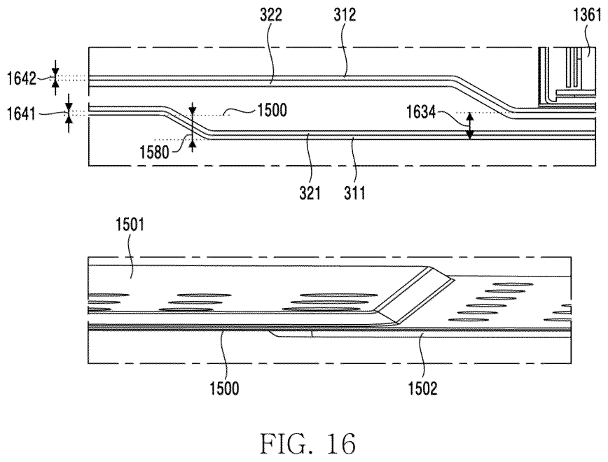

FIG. 16 indicates an example of a vapor chamber (e.g., a vapor chamber 220) having a single welding side. For the same descriptions, the same reference number may be used.

Referring to FIG. 16, a vapor chamber 220 may include a top side portion 1501 and a bottom side portion 1502 based on a base plane 1500. The vapor chamber 220 may include a first plate 311, a second plate 312, a first wick 321, and a second wick 322. Since a welding portion of the first plate 311 and the second plate 312 must be maintained on the same plane (e.g., the reference plane 1500) in the vapor chamber 220, a maximum possible step 1580 may be determined by a height of a minimum thickness of the vapor chamber 220 and a thickness (e.g., a thickness 1641of the first plate 311 and a thickness 1642 of the second plate 312) of a plate. For example, based on a side of the bottom side portion 1502, a height (e.g., a sum of the step 1580 and the thickness 1641 of the first plate 311) in the top side portion 1501 may be required to correspond to a value obtained by subtracting the thickness 1642 of the second plate 312 from the height of the second plate 312 in the bottom side portion 1502. As an example, the step 1580 may correspond to a difference between the thickness 1634 of the vapor chamber 220 and the thickness 1642 of the second plate 312 in the bottom side portion 1502.

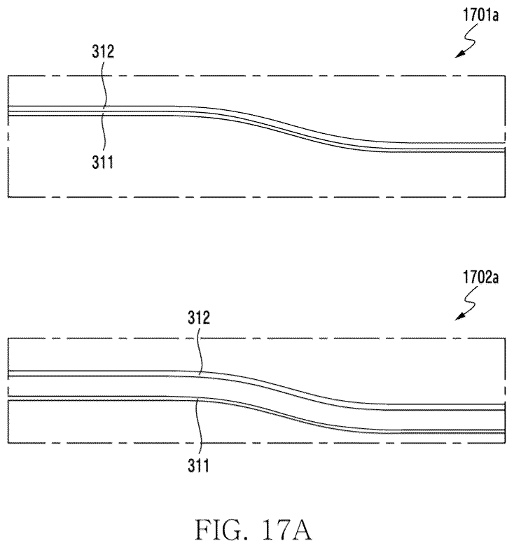

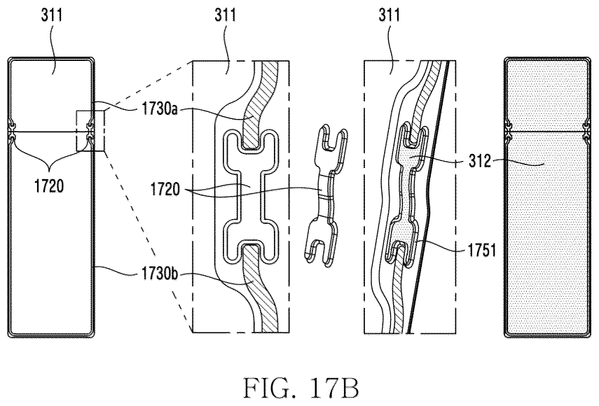

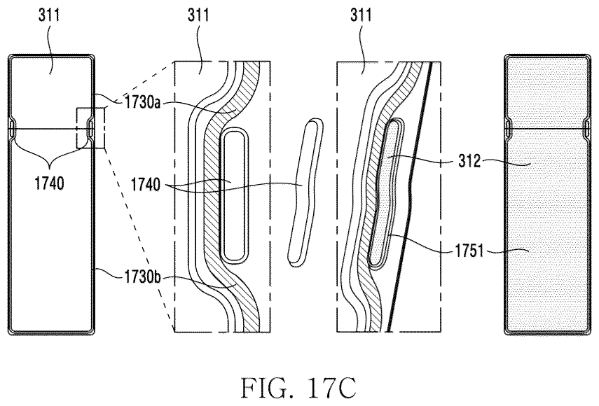

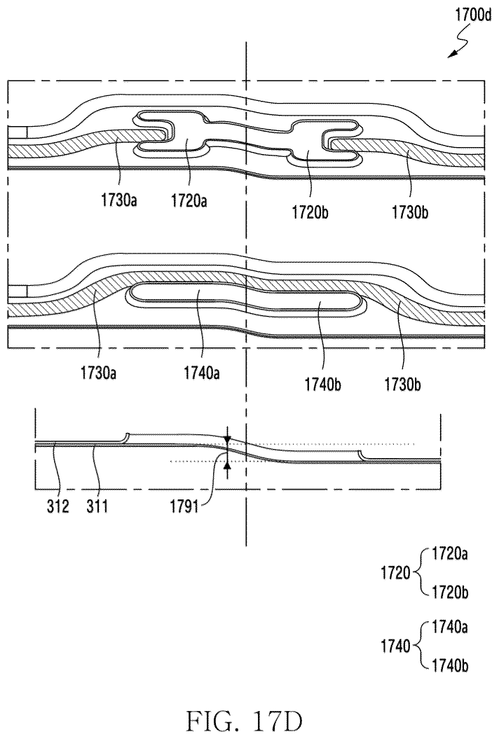

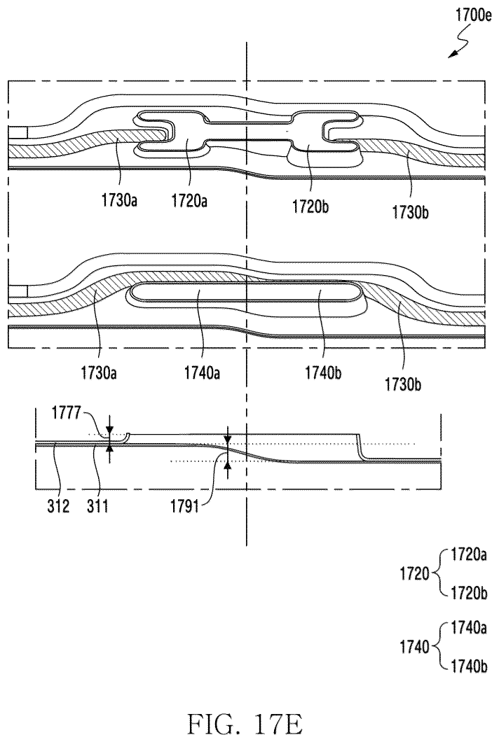

In FIGS. 15 and 16, a structure designed to have a single welding side in each of the top side portion 1501 and the bottom side portion 1502 of the vapor chamber 220 is illustrated, but embodiments of the present disclosure are not limited to the above example embodiment. Since the step 1580 depends on the thickness 1634 of the vapor chamber 220 and the thickness 1642 of the second plate 312 in the bottom side portion 1502, a welding side between the first plate 311 and the second plate 312 in the top side portion 1501 and a welding side between the first plate 311 and the second plate 312 in the bottom side portion 1502 may be different. The two welding sides may be connected in a curved state. Hereinafter, a structure of curved welding sides is described through FIGS. 17A to 17E.

FIGS. 17A, 17B, 17C, 17D, and 17E indicate examples of a vapor chamber (e.g., a vapor chamber 220) having a curved welding side. For the same descriptions, the same reference number may be used.

Referring to FIG. 17A, a first plate 311 and a second plate 312 of the vapor chamber 220 may be coupled to each other through welding. The first plate 311 and the second plate 312 may be coupled to form a space in which steam moves. Meanwhile, for a high step, a welding side between the first plate 311 and the second plate 312 in a top side portion 1501 may be curved. Likewise, a welding side between the first plate 311 and the second plate 312 in a bottom side portion 1502 may be curved. Each of the first plate 311 and the second plate 312 may be welded in a curved state. Meanwhile, leakage may occur due to a difference between a curvature of the first plate 311 and a curvature of the second plate 312 and/or poor welding. In order to weld the two plates in the curved state, bonding may be additionally applied to the curved portion. Hereinafter, examples of the bonding are described through FIGS. 17B to 17E.

Referring to FIG. 17B, the vapor chamber 220 may include the first plate 311 and the second plate 312. The first plate 311 may include a first flat portion, a second flat portion, and a first inclined portion between the first flat portion and the second flat portion. The second plate 312 may include a third flat portion, a fourth flat portion, and a second inclined portion between the third flat portion and the fourth flat portion. The same may be welded in flat portions. The first flat portion and the third flat portion may be welded to a top side of the vapor chamber 220. A first welding portion 1730a may be formed at the top side. The second flat portion and the fourth flat portion may be welded to a bottom side of the vapor chamber 220. A second welding portion 1730b may be formed at the bottom side.

Bonding may be performed in an inclined portion (e.g., the first inclined portion or the second inclined portion). According to an embodiment, the vapor chamber 220 may include a bonding portion 1720. For example, the bonding portion 1720 may have a shape surrounding each of the first welding portion 1730a and the second welding portion 1730b. For example, the bonding portion 1720 may have a structure surrounding each of the first welding portion 1730a and the second welding portion 1730b in a ‘ [symbol] ’ shape, that is, a horizontal line with a vertical line extending down from its left end and another horizontal line extending right from the bottom of the vertical one. A rib structure 1751 may be formed to surround the bonding portion 1720 so that an adhesive member of the bonding portion 1720 does not overflow. The first plate 311 and the second plate 312 may be coupled through the first welding portion 1730a, the second welding portion 1730b, and the bonding portion 1720.

Referring to FIG. 17C, the vapor chamber 220 may include the first plate 311 and the second plate 312. The first plate 311 may include a first flat portion, a second flat portion, and a first inclined portion between the first flat portion and the second flat portion. The second plate 312 may include a third flat portion, a fourth flat portion, and a second inclined portion between the third flat portion and the fourth flat portion. The same may be welded in flat portions. The first flat portion and the third flat portion may be welded to the top side of the vapor chamber 220. A first welding portion 1730a may be formed at the top side. The second flat portion and the fourth flat portion may be welded to a bottom side of the vapor chamber 220. A second welding portion 1730b may be formed at the bottom side.

Bonding may be performed in an inclined portion (e.g., the first inclined portion or the second inclined portion). According to an embodiment, the vapor chamber 220 may include a bonding portion 1740. For example, a welding portion including the first welding portion 1730a and the second welding portion 1730b may be formed to surround a periphery of a space between the first plate 311 and the second plate 312. The bonding portion 1740 may be additionally formed at a periphery of the welding portion. A rib structure 1751 may be formed to surround the bonding portion 1720 so that an adhesive member of the bonding portion 1740 does not overflow. The first plate 311 and the second plate 312 may be coupled through the first welding portion 1730a, the second welding portion 1730b, and the bonding portion 1720.

Referring to FIGS. 17D and 17E, since a gap between the first plate 311 and the second plate 312 should be sealed with an adhesive member (e.g., a bond), a member having good fluidity may be used as the adhesive member. On the other hand, the adhesive member may move from the top to the bottom due to a step 1791 between the top and the bottom in the inclined portion (e.g., the first inclined portion of the first plate 311 or the second inclined portion of the second plate 312). For example, the adhesive member in a first area 1720a of the bonding portion 1720 may move to a second area 1720b. For example, the adhesive member in a first area 1740a of the bonding portion 1740 may move to a second area 1740b. Due to this, adhesion performance may be weakened at the top. To reduce this, a height of a rib structure may be increased at the bottom side by the step 1791. For example, in a case that a minimum height for the adhesive member at the top is ‘r1, a height of a rib structure for the adhesive member at the bottom side may be ‘r1+step 1791’. According to an embodiment, a height of the rib structure at the bottom side of the vapor chamber 220 may be higher than a height 1777 of the rib structure at the top side. For example, a difference between the height of the rib structure at the bottom side of the vapor chamber 220 and the height 1777 of the rib structure at the top side may be greater than or equal to the step 1791 by a step 1791.

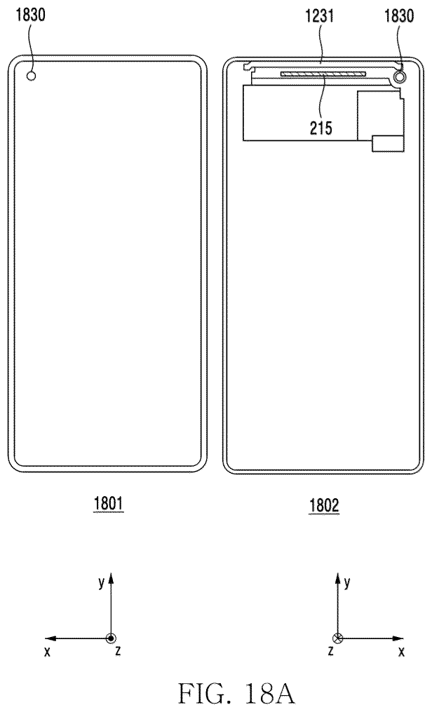

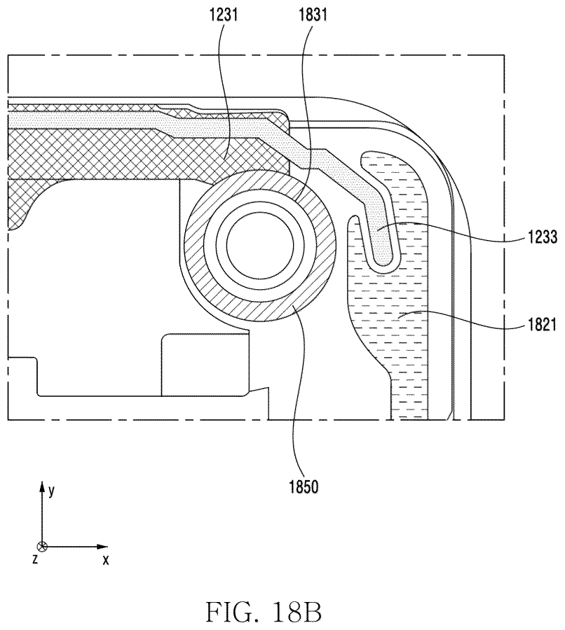

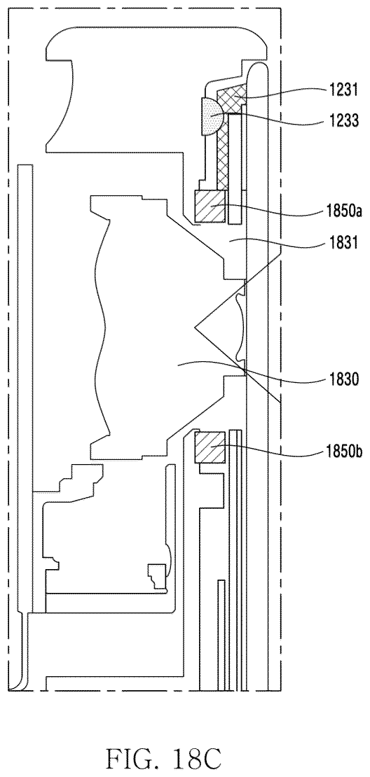

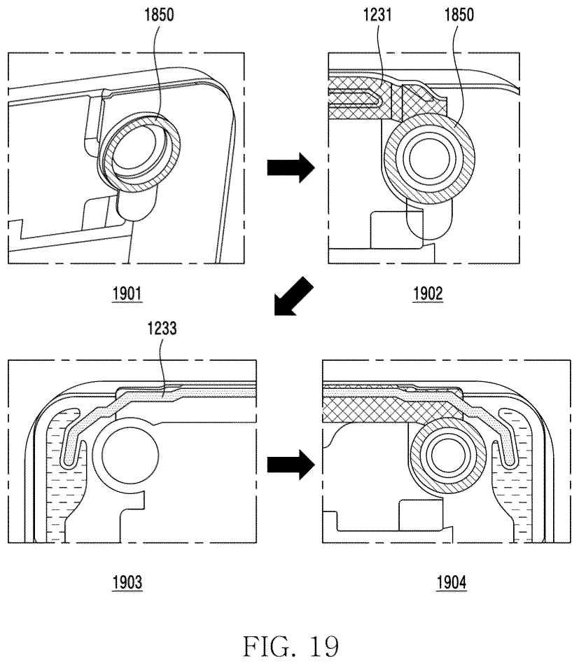

FIGS. 18A, 18B, 18C, and 19 indicate examples of a disposition of a display driver circuit (e.g., a display driver circuit 215) and a camera (e.g., a front camera 232) at a top side of an electronic device (e.g., an electronic device 101). For the same descriptions, the same reference number may be used.

Referring to FIG. 18A, an example 1801 indicates a front side of the electronic device 101. The electronic device 101 may include a camera 1830. An example 1802 indicates a rear side of the electronic device 101. A display driver circuit 215 connected to a display panel (e.g., a display panel 205) defining the front side of the electronic device 101 may be disposed on a top side of the electronic device 101. According to an embodiment, the display driver circuit 215 may be disposed closer to the top side of the electronic device 101 than to a bottom side of the electronic device 101. Due to the display driver circuit 215, the camera 1830 may be disposed close to a lateral side at the top. In order to display an image displayed through a display more widely, for example, in order to prevent the image from being cut by the camera 1830, the camera 1830 may be required to be disposed more outwardly. The electronic device 101 may include a molding part 1231 for protecting a bending portion of the display panel 205. As the camera 1830 is disposed outwardly, the camera 1830 may become closer to the molding part 1231. For example, as a hole of the molding part 1231 and the camera 1830 approaches, foreign substance or an adhesive member may be introduced. To reduce this, according to an embodiment, a structure for preventing the foreign substance may be provided in the hole of the camera 1830.

Referring to FIGS. 18B and 18C, a sponge 1850 (a sponge 1850a or 1850b in FIG. 18C) may be disposed to surround a hole 1831 of the camera 1830. The molding part 1231 may be disposed to surround a sidewall of the sponge 1850. Accordingly, a width of the molding part 1231 for protecting a bending portion of the display panel 205 may be secured. The electronic device 101 may include a bonding portion 1233 and a waterproof tape 1821 for waterproofing. It may be resolved that the adhesive member of the bonding portion 1233 flow through the sponge 1850 and flow into the hole 1831.

Referring to FIG. 19, the sponge 1850, the molding part 1231, and the bonding portion 1233 may be disposed in an order of an example 1901, an example 1902, an example 1903, and an example 1904. For example, in the example 1901, the sponge 1850 may be disposed to surround the hole 1831 of the camera 1830. Thereafter, in the example 1902, molding for the display panel 205 of the electronic device 101 may be perform. The molding part 1231 for the display panel 205 may be formed. In the example 1903, the bonding portion 1233 for waterproofing may be applied. In the example 1904, assembly may be completed.

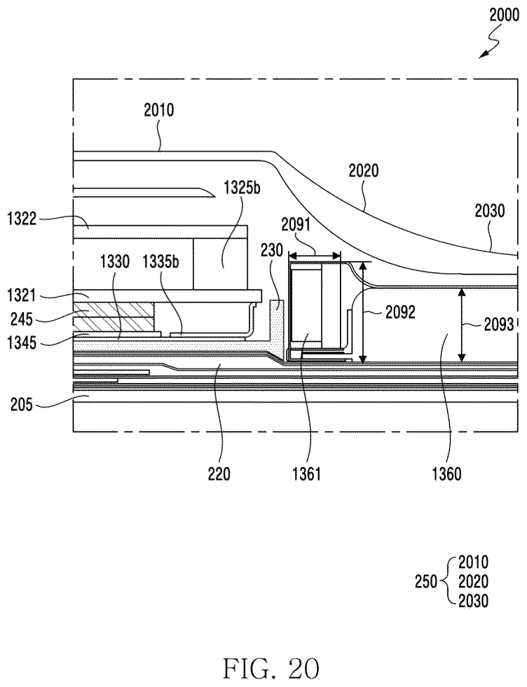

FIG. 20 indicates an example of a battery in an electronic device (e.g., an electronic device 101) including a slope-shape back cover. For the same descriptions, the same reference number may be used.

Referring to FIG. 20, the electronic device 101 may include a plurality of components. For example, the electronic device 101 may include a display panel 205, a metal frame 230, a battery cell 1360, and/or a protection circuit module (PCM) assembly 1361. For example, the electronic device 101 may include a vapor chamber 220. The vapor chamber 220 may include a first plate 311 and a second plate 312. The first plate 311 and the second plate 312 may be coupled to form an internal volume. A tape 1355 for the vapor chamber 220 may be disposed between the metal frame 230 and the vapor chamber 220. The electronic device 101 may include components for the processor 245. The electronic device 101 may include PCBs (e.g., a first PCB 1321 and a second PCB 1322) and/or interposer 1325a or 1325b for the processor 245. The electronic device 101 may include a heat dissipation sheet 1330 for electromagnetic shielding, a shield can 1335a or 1335b for the processor 245, and/or a TIM 1345 for the processor 245.

According to an embodiment, a rear cover 250 of the electronic device 101 may include a top side flat portion 2010, an inclined portion 2020, and a bottom side flat portion 2030. The inclined portion 2020 may correspond to a slope in which the top side flat portion 2010 and the bottom side flat portion 2030 have a constant curvature. The electronic device 101 may have a thickness of two stages. The electronic device 101 may have a first thickness between the top side flat portion 2010 and the display panel 205 and a second thickness between the bottom side flat portion 2030 and the display panel 205. A plurality of components (e.g., a display FPCB, a front camera, a rear camera, a PCB, and a shim socket) may be included between the top side flat portion 2010 and the display panel 205. A plurality of components (e.g., USB, a bottom side speaker 249b, a motor, the battery cell 1360, and the PCM assembly 1361) may be included between the bottom side flat portion 2030 and the display panel 205.

According to an embodiment, a part of the PCM assembly 1361 may be disposed higher than the battery cell 1360. The PCM assembly 1361 may include circuitry for controlling and managing the battery cell 1360. For example, the PCM assembly 1361 may include the PCB, an FPCB, a PCM, a pure gauge circuitry for measuring a battery capacity, one or more passive elements, positive electrode tabs and/or negative electrode tabs connected to the battery cell 1360. Because the rear cover 250 does not have a single height but has heights of two stages through the inclined portion 2020, a part of the PCM assembly 1361 may be disposed under the top side flat portion 2010 or the inclined portion 2020. For example, the PCM assembly 1361 may occupy a space having a width 2091 of a first value and a height 2092 of a second value. The first value of the width 2091 may be less than ae value of the height 2093 of the battery cell 1360. The second value of the height 2092 may be greater than a value of the height 2093 of the battery cell 1360. In a case that the rear cover 250 has a single height, the PCM assembly 1361 is required to be inclined. However, since the rear cover 250 includes the inclined portion 2020, the PCM assembly 1361 may be disposed to have the height 2092 of the second value. Due to the disposition of the PCM assembly 1361, as a width of the PCM assembly 1361 decreases, a capacity of the battery cell 1360 may be further secured.

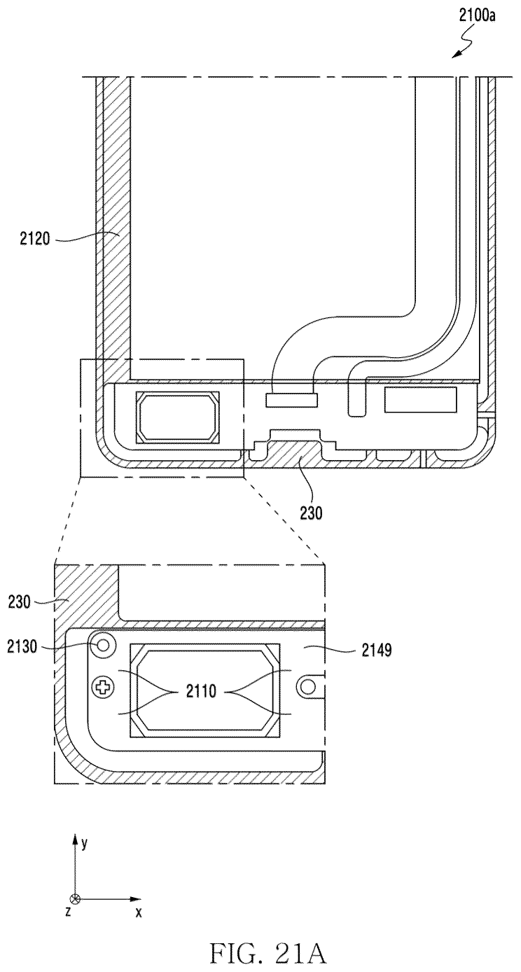

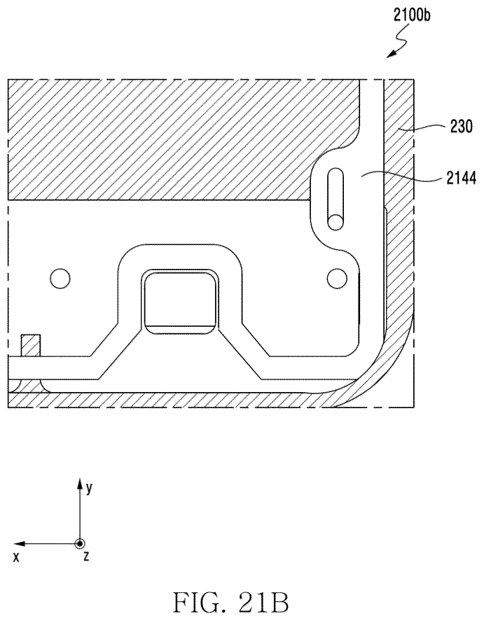

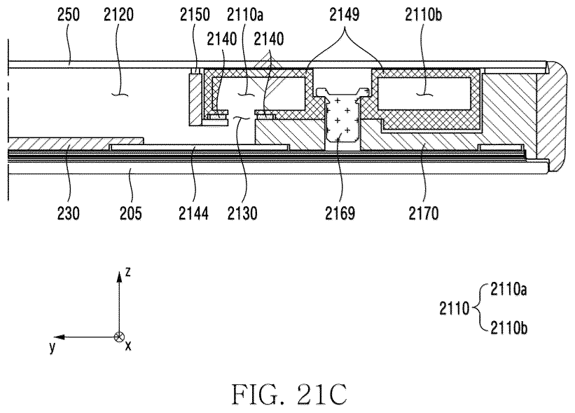

FIGS. 21A, 21B, and 21C indicate examples of components forming a back volume space for a speaker (e.g., a bottom side speaker 249b).

Referring to FIG. 21A, an example 2100a indicates a drawing (e.g., a drawing viewed in a (+)z-axis direction) of an electronic device 101 viewed from a rear side. The electronic device 101 may include a metal frame 230. The electronic device 101 may include a speaker structure 2149 forming a first back volume space 2110. As a back volume space is larger, it is more advantageous to improve speaker performance. As an extent of a battery increases at a bottom side of the electronic device 101, the back volume space for the speaker may become insufficient. According to an embodiment, the electronic device 101 may include a part (e.g., a lateral side facing a (−)x-axis direction) of the metal frame 230 and a second back volume space 2120 formed through the rear cover 250. A connection hole 2130 may be formed to connect the first back volume space 2110 and the second back volume space 2120.

Referring to FIG. 21B, an example 2100b indicates a drawing (e.g., a drawing viewed in the (−)z-axis direction) of the electronic device 101 viewed from a front side. A tape 2144 (hereinafter, a display tape) for a display panel 205 may be disposed adjacent to a part of the metal frame 230 (e.g., a lateral side facing the (−)x-axis direction).

Referring to FIG. 21C, the electronic device 101 may include a display panel 205, the metal frame 230, a rear cover 250, a sponge 2140, a rear cover tape 2150, a display tape 2144, a speaker structure 2149, a screw 2159 and a non-conductive portion 2170. The second back volume space 2120 may be formed through the display panel 205, the display tape 21144, the rear cover 250, the rear cover tape 2150, the metal frame 230, and the non-conductive portion 2170. The first back volume space 2110a or 2110b formed through the speaker structure 2149 may be connected to the second back volume space 2120 through a connection hole 2130. The connection hole 2130 may be formed in an area of the metal frame 230. As a sealed space is formed through an assembly of the rear cover 250, the entire back volume of the speaker including the first back volume space 2110a or 2110b and the second back volume space 2120 may be configured.

In embodiments of the present disclosure, an electronic device 101 is provided. The electronic device 101 may include a housing, a display panel that included in at least a part of a front side of the housing, a display driver integrated circuit (DDI) 215 connected to the display panel and disposed to be closer to a top side of the housing than a bottom side of the housing, a processor 245 including processing circuitry and disposed in the housing, and a vapor chamber 220 disposed between the DDI 215 and the processor 245. The vapor chamber 220 may include a first heat conductivity member disposed to dissipate heat generated by the DDI 215 and including a first plate 311 and a first wick 321 in contact with the first plate 311, and a second heat conductivity member disposed to dissipate heat generated by the processor 245 and including a second plate 312 and a second wick 322 in contact with the second plate 312. The first wick 321 may be disposed in an internal space disposed between the first plate 311 and the second plate 312. The first wick 321 may include a first evaporation portion overlapping at least a part of the DDI 215 and receiving heat generated by the DDI 215, a first condensation portion spaced apart from the DDI 215 and receiving heat from the DDI 215, and a first path portion connecting the first evaporation portion to the first condensation portion. The second wick 322 may be disposed in the internal space. The second wick 322 may include a second evaporation portion overlapping at least a part of the processor 245 and receiving heat generated by the processor 245, a second condensation portion spaced apart from the processor 245, and a second path portion connecting the second evaporation portion to the second condensation portion. The first path portion of the first wick 321 and the second path portion of the second wick 322 may not overlap each other.

In embodiments of the present disclosure, an electronic device 101 is provided. The electronic device 101 may include a housing, a display panel included in at least a part of a front side of the housing, a display driver integrated circuit (DDI) 215 connected to the display panel and disposed to be closer to a top side of the housing than a bottom side of the housing, a processor 245 including processing circuitry and disposed in the housing, and a vapor chamber 220 disposed between the DDI 215 and the processor 245. The vapor chamber 220 may include a first heat conductivity member disposed to dissipate heat generated by the DDI 215 and including a first plate 311 and a first wick 321 in contact with the first plate 311, and a second heat conductivity member disposed to dissipate heat generated by the processor 245 and including a second plate 312 and a second wick 322 in contact with the second plate 312. Each of the first wick 321 and the second wick 322 may be disposed in an internal space between the first plate 311 and the second plate 312. The first plate 311 may have a first set of protruding portions disposed on an inner side of the first plate 311. The second plate 312 may have a second set of protruding portions disposed on an inner side of the second plate 312. The first wick 321 may include holes for protruding portions included in the first set of the protruding portions. The second wick 322 may include holes for protruding portions included in the second set of the protruding portions.

For example, the first plate 311 may include a first area contacting the first wick and a second area different from the first area. The second plate 312 may include may include a third area contacting the second wick and a fourth area different from the third area. The first plate 311 may have a first set of protruding portions disposed on the second area of the first plate 311 to support the second wick. The second plate 312 may have a second set of protruding portions disposed on the fourth area of the second plate 312 to support the first wick. The second area of the first plate 311 and the fourth area of the second plate 312 do not overlap each other.

For example, the DDI 215 may be disposed over an outer side of the first plate 311 opposite to a side contacting the first wick. The processor 245 may be disposed beneath an outer side of the second plate 312 opposite to a side contacting the second wick.

In embodiments of the present disclosure, an electronic device 101 is provided. The electronic device 101 may include a housing, a display panel 205 included in at least a part of a front side of the housing, a display driver circuit 215 connected to the display panel 205 to be closer to a top side of the housing than a bottom side of the housing, at least one processor 245 including processing circuitry and disposed in the housing, and a vapor chamber 220 between the display driver circuit 215 and the at least one processor 245. The vapor chamber may include a first plate 311 disposed to be closer to the display driver circuit 215 than the at least one processor 245, a second plate 312 to be closer to the at least one processor 245 than the display driver circuit 215, the second plate 312 coupled to the first plate 311 to have an internal space between the first plate 311 and the second plate 312, a first evaporation portion overlapping the display driver circuit 215, a first condensation portion not overlapping the display driver circuit 215, and a first path portion connecting the first evaporation portion to the first condensation portion, a first wick disposed in the internal space and in contact with an inner side of the first plate 311, and a second evaporation portion overlapping the at least one processor 245, a second condensation portion not overlapping the at least one processor 245, and a second path portion connecting a second evaporation portion to a second condensation portion, the second wick 322 disposed in the internal space and in contact with an inner side of the second plate 312. At least a part of the first path portion of the first wick and at least a part of the second path portion of the second wick may not overlap each other.

For example, an inner side of the first plate 311 may include a first wick area contacting the first wick and a first support area different from the first wick area. An inner side of the second plate 312 may include a second wick area contacting the second wick and a second support area different from the second wick area. The first plate 311 may have a first set of protruding portions disposed on the first support area of the first plate 311. The second plate 312 may have a second set of protruding portions disposed on the second support area of the second plate 312. All of the protruding portions included in the first set of the protruding portions and all of the protruding portions included in the second set of the protruding portions may not overlap each other.

For example, a first heat source for the display driver circuit 215 on an outer side of the first plate 311 may overlap the first wick area and may not overlap the first support area. A second heat source for the at least one processor 245 on an outer side of the second plate 312 may overlap the second wick area and may not overlap the second support area.

For example, the first condensation portion and the second condensation portion may overlap each other. The first plate 311 may have a third set of protruding portions disposed on a part of the first wick area of the first plate 311, the part corresponding to the first condensation portion. The second plate 312 may have a fourth set of protruding portions disposed on a part of the second wick area of the second plate 312, the part corresponding to the second condensation portion.

For example, the first condensation portion may include holes for protruding portions included in the third set of the protruding portions. The second condensation portion may include holes for protruding portions included in the fourth set of the protruding portions.

For example, density of protruding portions included in a first set of the protruding portions may be higher than density of protruding portions included in a third set of the protruding portions. Density of protruding portions included in a second set of the protruding portions may be higher than density of protruding portions included in a fourth set of the protruding portions.

For example, the first path portion may have a longitudinal direction from the bottom side of the housing to the top side of the housing. The second path portion may have a longitudinal direction from the bottom side of the housing to the top side of the housing. The first path portion and the second path portion may be spaced apart from each other in the horizontal direction.

For example, the first plate 311 may include a first flat portion, a second flat portion, and a first inclined portion between the first flat portion and the second flat portion. The second plate 312 may include a third flat portion, a fourth flat portion, and a second inclined portion between the third flat portion and the fourth flat portion. A width between the first inclined portion and the second inclined portion may be wider than a distance between the first flat portion and the third flat portion. The width between the first inclined portion and the second inclined portion may be wider than a distance between the second flat portion and the fourth flat portion.

For example, the second flat portion of the first plate 311 may be spaced apart from a base plane corresponding to the first flat portion of the first plate 311. The third flat portion of the second plate 312 may be spaced apart from the base plane corresponding to the fourth flat portion of the second plate 312. The base plane may include a portion where the first plate 311 and the second plate 312 are welded.

For example, the electronic device 101 may include a battery. The battery may be disposed on the fourth flat portion of the second plate 312. At least one component for the display driver circuit 215 may be disposed on the first flat portion of the first plate 311.

For example, the housing may include a back cover having a top flat portion, a bottom flat portion, and an inclined portion between the top flat portion and the bottom flat portion. The battery may include a protection circuit module (PCM) assembly and a battery cell. A part of the PCM assembly may be disposed to be higher than the battery cell. The battery cell is disposed beneath the bottom flat portion or the inclined portion of the housing.

For example, the electronic device 101 may include a thermal interface material (TIM) in contact with the first plate 311 of the vapor chamber 220, and a film disposed between the TIM and the display driver circuit.

For example, the electronic device 101 may include a printed circuit board (PCB) on which the at least one processor 245 is disposed, a thermal interface material (TIM) in contact with the at least one processor 245, a heat dissipation sheet in contact with the TIM, and a metal frame in contact with the heat dissipation sheet and the second plate 312 of the vapor chamber 220.

For example, the electronic device 101 may include a camera that is closer to the top side of the housing than the bottom side of the housing, and a sponge surrounding a hole of the camera. The sponge may contact with a molding part for the display panel 205.

For example, the electronic device 101 may include a speaker structure forming a first back volume space, a metal frame, a display tape for the display panel, and a back glass tape for the housing. The display panel 205, the display tape, the back glass tape, the metal frame, and the housing may form a second back volume space. The speaker structure may have a connection hole for the second back volume space.

In embodiments of the present disclosure, an electronic device 101 is provided. The electronic device 101 may include a housing, a display panel 205 included in at least a part of a front side of the housing, a display driver circuit 215 connected to the display panel 205 closer to a top side of the housing than a bottom side of the housing, at least one processor 245 including processing circuitry and disposed in the housing, and a vapor chamber 220 between the display driver circuit 215 and the at least one processor 245. The vapor chamber may include a first plate 311 closer to the display driver circuit 215 than the at least one processor 245, a second plate 312 closer to the at least one processor 245 than the display driver circuit 215, the second plate 312 coupled to the first plate 311 to have an internal space between the first plate 311 and the second plate 312, a first wick 1021 disposed in the internal space and in contact with an inner side of the first plate 311, and a second wick 1022 disposed in the internal space and in contact with an inner side of the second plate 312. The first plate 311 may have a first set of protruding portions disposed on the inner side of the first plate 311. The second plate 312 may have a second set of protruding portions disposed on the inner side of the second plate 312. The first wick 1021 may include holes for protruding portions included in the first set of the protruding portions. The second wick 1022 may include holes for protruding portions included in the second set of the protruding portions.

For example, the first set of the protruding portions may include first protruding portions arranged in a direction from a top side of the housing to a bottom side of the housing. The second set of the protruding portions may include second protruding portions arranged in a direction from the top side of the housing to the bottom side of the housing. In one or more embodiments, the first protruding portions and the second protruding portions may be alternately arranged.

For example, the first plate 311 may include a first flat portion, a second flat portion, and a first inclined portion between the first flat portion and the second flat portion. The second plate 312 may include a third flat portion, a fourth flat portion, and a second inclined portion between the third flat portion and the fourth flat portion. A width between the first inclined portion and the second inclined portion may be wider than a distance between the first flat portion and the third flat portion. The width between the first inclined portion and the second inclined portion may be wider than a distance between the second flat portion and the fourth flat portion.

For example, the second flat portion of the first plate 311 may be spaced apart from a base plane corresponding to the first flat portion of the first plate 311. The third flat portion of the second plate 312 may be spaced apart from the base plane corresponding to the fourth flat portion of the second plate 312. The base plane may include a portion where the first plate 311 and the second plate 312 are welded.

For example, the electronic device 101 may include a battery. The battery may be disposed on the fourth flat portion of the second plate 312. At least one component for the display driver circuit 215 may be disposed on the first flat portion of the first plate 311.

In embodiments of the present disclosure, an electronic device 101 is provided. The electronic device 101 may include a housing, a first heat source and a second heat source disposed in the housing, and a vapor chamber between the first heat source and the second heat source. The vapor chamber may include a first plate closer to the first heat source than the second heat source, a second plate closer to the second heat source than the first heat source, the second plate coupled to the first plate to define an internal space between the first plate and the second plate, a first wick disposed in the internal space and in contact with at least a part of an inner side of the first plate, the first wick including a plurality of holes, and a second wick disposed in the internal space and in contact with at least a part of an inner side of the second plate, the second wick including a plurality of holes. The first plate may include a first support area formed in an inner direction of the vapor chamber and having a first set of protruding portions penetrating a plurality of holes included in the first wick, and a first heat source area on which the first set of the protruding portions are not disposed, directly contacting the first heat source or indirectly contacting the first heat source through at least one component. The second plate may include a second support area formed in an inner direction of the vapor chamber and having a second set of protruding portions penetrating a plurality of holes included in the second wick, and a second heat source area on which the second set of the protruding portions are not disposed, directly contacting the second heat source or indirectly contacting the second heat source through at least one component.

For example, at least a part of the first support area and at least a part of the second support area may overlap each other. Within an area formed by overlapping at least a part of the first support area and at least a part of the second support area each other, at least a part of protruding portions included in the first set of the protruding portions and at least a part of protruding portions included in the second set of the protruding portions may not overlap each other.

For example, the first set of the protruding portions, the second wick, and the second plate may sequentially contact each other. The second set of the protruding portions, the first wick, and the first plate may sequentially contact each other.

For example, the housing may include a rear cover having a top flat portion, a bottom flat portion, and an inclined portion between the top flat portion and the bottom flat portion. The first heat source and the second heat source may be disposed under the top flat portion. The electronic device may include a battery cell disposed under the bottom flat portion or the inclined portion.

For example, the first plate may include a first flat portion where the first heat source is disposed and a second flat portion at least partially disposed under the bottom flat portion and forming a step with the first flat portion. The second plate may include a third flat portion where the second heat source is disposed and a fourth flat portion at least partially disposed under the bottom flat portion and forming a step with the third flat portion. A distance between the first flat portion and the third flat portion may be equal to or greater than a distance between the second flat portion and the fourth flat portion.

For example, the vapor chamber may include a bonding portion for connecting the first flat portion and the second flat portion, a rib structure surrounding the bonding portion. A difference between a height of the rib structure at a bottom side of the housing and a height of the rib structure at a top side of the housing may be greater than or equal to the step of the first plate or the step of the second plate.

For one or more embodiments, at least one of components described in one or more of preceding drawings may be configured to perform one or more operations, techniques, processes and/or methods as described in the present disclosure. For example, the processor (e.g., a baseband processor) described in the present disclosure in relation to one or more of the preceding drawings may be configured to operate according to one or more examples described in the present disclosure. According to an embodiment, circuitry associated with a user equipment (UE), a base station, a network element, and the like as described above in relation to one or more of the previous drawings may be configured to operate according to one or more examples described here.

Any of the embodiments described above may be combined with any other embodiment (or combination of embodiments) unless otherwise explicitly stated. The above-described description of one or more implementations provides an example and a description, but is not intended to limit or to be exhaust a scope of embodiments in a precise form disclosed. In light of the above teachings, modification and deformation may be made or may be obtained from a practice of various embodiments.

The electronic device according to various embodiments may be one of various types of electronic devices. The electronic devices may include, for example, a portable communication device (e.g., a smartphone), a computer device, a portable multimedia device, a portable medical device, a camera, a wearable device, or a home appliance. According to an embodiment of the disclosure, the electronic devices are not limited to those described above.

It should be appreciated that various embodiments of the present disclosure and the terms used therein are not intended to limit the technological features set forth herein to particular embodiments and include various changes, equivalents, or replacements for a corresponding embodiment. With regard to the description of the drawings, similar reference numerals may be used to refer to similar or related elements. A singular form of a noun corresponding to an item may include one or more of the things unless the relevant context clearly indicates otherwise. As used herein, each of such phrases as “A or B,” “at least one of A and B,” “at least one of A or B,” “A, B, or C,” “at least one of A, B, and C,” and “at least one of A, B, or C,” may include any one of or all possible combinations of the items enumerated together in a corresponding one of the phrases. As used herein, such terms as “1st” and “2nd,” or “first” and “second” may be used to simply distinguish a corresponding component from another, and does not limit the components in other aspect (e.g., importance or order). It is to be understood that if an element (e.g., a first element) is referred to, with or without the term “operatively” or “communicatively”, as “coupled with,” or “connected with” another element (e.g., a second element), it means that the element may be coupled with the other element directly (e.g., through a wire or wires), wirelessly, or via a third element.

As used in connection with various embodiments of the disclosure, the term “module” may include a unit implemented in hardware, software, or firmware, and may interchangeably be used with other terms, for example, “logic,” “logic block,” “part,” or “circuitry”. A module may be a single integral component, or a minimum unit or part thereof, adapted to perform one or more functions. For example, according to an embodiment, the module may be implemented in a form of an application-specific integrated circuit (ASIC).

Various embodiments as set forth herein may be implemented as software (e.g., the program 140) including one or more instructions that are stored in a storage medium (e.g., internal memory 136 or external memory 138) that is readable by a machine (e.g., the electronic device 101). For example, a processor (e.g., the processor 120) of the machine (e.g., the electronic device 101) may invoke at least one of the one or more instructions stored in the storage medium, and execute it, with or without using one or more other components under the control of the processor. This allows the machine to be operated to perform at least one function according to the at least one instruction invoked. The one or more instructions may include a code generated by a complier or a code executable by an interpreter. The machine-readable storage medium may be provided in the form of a non-transitory storage medium. Wherein, the term “non-transitory” simply means that the storage medium is a tangible device, and does not include a signal (e.g., an electromagnetic wave), but this term does not differentiate between a case in which data is semi-permanently stored in the storage medium and a case in which the data is temporarily stored in the storage medium.

According to an embodiment, a method according to various embodiments of the disclosure may be included and provided in a computer program product. The computer program product may be traded as a product between a seller and a buyer. The computer program product may be distributed in the form of a machine-readable storage medium (e.g., compact disc read only memory (CD-ROM)), or be distributed (e.g., downloaded or uploaded) online via an application store (e.g., PlayStore™), or between two user devices (e.g., smart phones) directly. If distributed online, at least part of the computer program product may be temporarily generated or at least temporarily stored in the machine-readable storage medium, such as memory of the manufacturer's server, a server of the application store, or a relay server.

According to various embodiments, each component (e.g., a module or a program) of the above-described components may include a single entity or multiple entities, and some of the multiple entities may be separately disposed in different components. According to various embodiments, one or more of the above-described components may be omitted, or one or more other components may be added. Alternatively or additionally, a plurality of components (e.g., modules or programs) may be integrated into a single component. In such a case, according to various embodiments, the integrated component may still perform one or more functions of each of the plurality of components in the same or similar manner as they are performed by a corresponding one of the plurality of components before the integration. According to various embodiments, operations performed by the module, the program, or another component may be carried out sequentially, in parallel, repeatedly, or heuristically, or one or more of the operations may be executed in a different order or omitted, or one or more other operations may be added.

What is claimed is

1. An electronic device comprising:
a housing;
a display panel defining at least a part of a front side of the housing;
a display driver integrated circuit (DDI) connected to the display panel and closer to a top side of the housing than a bottom side of the housing;
a processor in the housing and comprising processing circuitry; and
a vapor chamber between the DDI and the processor,
wherein the vapor chamber comprises:
a first heat conductivity member disposed to dissipate heat generated by the DDI and including a first plate and a first wick in contact with the first plate, and
a second heat conductivity member disposed to dissipate heat generated by the processor and including a second plate and a second wick in contact with the second plate,
wherein the first wick is disposed in an internal space disposed between the first plate and the second plate and includes:
a first evaporation portion overlapping at least a part of the DDI and receiving heat generated by the DDI,
a first condensation portion spaced apart from the DDI and receiving heat from the DDI, and
a first path portion connecting the first evaporation portion to the first condensation portion,
wherein the second wick is disposed in the internal space and includes:
a second evaporation portion overlapping at least a part of the processor and receiving heat generated by the processor,
a second condensation portion spaced apart from the processor, and
a second path portion connecting the second evaporation portion to the second condensation portion, and
wherein the first path portion of the first wick and the second path portion of the second wick do not overlap each other.

2. The electronic device of claim 1, wherein the first plate comprises a first area contacting the first wick and a second area different from the first area,
wherein the second plate comprises a third area contacting the second wick and a fourth area different from the third area,
wherein the first plate comprises a first set of protruding portions on the second area of the first plate to support the second wick,
wherein the second plate comprises a second set of protruding portions on the fourth area of the second plate to support the first wick, and
wherein the second area of the first plate and the fourth area of the second plate do not overlap each other.

3. The electronic device of claim 2, wherein the DDI is disposed over an outer side of the first plate opposite to a side contacting the first wick, and
wherein the processor is disposed beneath an outer side of the second plate opposite to a side contacting the second wick.

4. The electronic device of claim 2, wherein the first condensation portion and the second condensation portion overlap each other,
wherein the first plate comprises a third set of protruding portions on a first part of a first wick area of the first plate, the first part corresponding to the first condensation portion,
wherein the second plate comprises a fourth set of protruding portions on a second part of a second wick area of the second plate, the second part corresponding to the second condensation portion, and
wherein protruding portions included in the third set of the protruding portions and protruding portions included in the fourth set of the protruding portions do not overlap each other.

5. The electronic device of claim 4, wherein the first condensation portion comprises first holes corresponding to the third set of the protruding portions, and
wherein the second condensation portion comprises second holes corresponding to the fourth set of the protruding portions.

6. The electronic device of claim 1, wherein the first path portion has a longitudinal direction from the bottom side of the housing to the top side of the housing,
wherein the second path portion has a longitudinal direction from the bottom side of the housing to the top side of the housing, and
wherein the first path portion and the second path portion are spaced apart from each other in a horizontal direction.

7. The electronic device of claim 1, wherein the first plate comprises a first flat portion, a second flat portion, and a first inclined portion between the first flat portion and the second flat portion,
wherein the second plate comprises a third flat portion, a fourth flat portion, and a second inclined portion between the third flat portion and the fourth flat portion,
wherein a width between the first inclined portion and the second inclined portion is wider than a first distance between the first flat portion and the third flat portion, and
wherein the width between the first inclined portion and the second inclined portion is wider than a second distance between the second flat portion and the fourth flat portion.

8. The electronic device of claim 7, wherein the second flat portion of the first plate is spaced apart from a base plane corresponding to the first flat portion of the first plate,
wherein the third flat portion of the second plate is spaced apart from the base plane corresponding to the fourth flat portion of the second plate, and
wherein the first plate and the second plate are welded at a portion of the base plane.

9. The electronic device of claim 7, further comprising a battery on the fourth flat portion of the second plate,
wherein at least one component for the DDI is on the first flat portion of the first plate.

10. The electronic device of claim 9, wherein the housing comprises a back cover having a top flat portion, a bottom flat portion, and an inclined portion between the top flat portion and the bottom flat portion,
wherein the battery comprises a protection circuit module (PCM) assembly and a battery cell,
wherein a part of the PCM assembly is disposed to be higher than the battery cell, and
wherein the battery cell is disposed beneath the bottom flat portion or the inclined portion of the housing.

11. The electronic device of claim 1, further comprising:
a thermal interface material (TIM) in contact with the first plate of the vapor chamber; and
a film between the TIM and the DDI.

12. The electronic device of claim 1, further comprising:
a printed circuit board (PCB) on which the processor is disposed,
a thermal interface material (TIM) in contact with the processor;
a heat dissipation sheet in contact with the TIM; and
a metal frame in contact with the heat dissipation sheet and the second plate of the vapor chamber.

13. The electronic device of claim 1, further comprising:
a camera that is closer to the top side of the housing than the bottom side of the housing; and
a sponge surrounding a hole of the camera,
wherein the sponge contacts a molding part for the display panel.

14. The electronic device of claim 1, further comprising:
a speaker structure forming a first back volume space;
a metal frame;
a display tape on the display panel; and
a back glass tape on the housing,
wherein the display panel, the display tape, the back glass tape, the metal frame, and the housing define a second back volume space, and
wherein the speaker structure has a connection hole for the second back volume space.

15. An electronic device comprising:
a housing;
a first heat source in the housing;
a second heat source in the housing;
a vapor chamber between the first heat source and the second heat source,
wherein the vapor chamber comprises:
a first plate that is closer to the first heat source than the second heat source,
a second plate that is closer to the second heat source than the first heat source, the second plate being coupled to the first plate to define an internal space between the first plate and the second plate,
a first wick disposed in the internal space and in contact with at least a part of an inner side of the first plate, the first wick comprising a plurality of first holes, and
a second wick disposed in the internal space and in contact with at least a part of an inner side of the second plate, the second wick comprising a plurality of second holes,
wherein the first plate comprises:
a first support area in a first inner direction of the vapor chamber and comprising a first set of protruding portions penetrating the plurality of first holes in the first wick, and
a first heat source area on which the first set of the protruding portions are not disposed, and directly contacting the first heat source or indirectly contacting the first heat source through at least one component, and
wherein the second plate comprises:
a second support area in a second inner direction of the vapor chamber and comprising a second set of protruding portions penetrating the plurality of second holes in the second wick, and
a second heat source area on which the second set of the protruding portions are not disposed, and directly contacting the second heat source or indirectly contacting the second heat source through at least one component.

16. The electronic device of claim 15, wherein at least a part of the first support area and at least a part of the second support area overlap each other, and
wherein, within an area formed by overlapping at least the part of the first support area and at least the part of the second support area each other, at least a part of protruding portions included in the first set of the protruding portions and at least a part of protruding portions included in the second set of the protruding portions do not overlap each other.

17. The electronic device of claim 15, wherein the first set of the protruding portions, the second wick, and the second plate sequentially contact each other, and
wherein the second set of the protruding portions, the first wick, and the first plate sequentially contact each other.

18. The electronic device of claim 15, wherein the housing comprises a rear cover having a top flat portion, a bottom flat portion, and an inclined portion between the top flat portion and the bottom flat portion,
wherein the first heat source and the second heat source are under the top flat portion, and
wherein the electronic device further comprises a battery cell under the bottom flat portion or the inclined portion.

19. The electronic device of claim 18, wherein the first plate comprises:
a first flat portion where the first heat source is disposed, and
a second flat portion at least partially under the bottom flat portion and forming a first step with the first flat portion,
wherein the second plate comprises:
a third flat portion where the second heat source is disposed, and
a fourth flat portion at least partially under the bottom flat portion and forming a second step with the third flat portion, and
wherein a first distance between the first flat portion and the third flat portion is equal to or greater than a second distance between the second flat portion and the fourth flat portion.

20. The electronic device of claim 19, wherein the vapor chamber comprises:
a bonding portion for connecting the first flat portion with the second flat portion; and
a rib structure surrounding the bonding portion, and
wherein a difference between a first height of the rib structure at a bottom side of the housing and a second height of the rib structure at a top side of the housing is greater than or equal to the first step of the first plate or the second step of the second plate.
